(19) United States
(12) Patent Application Publication
(10) Pub. No.: US 2024/0046100 A1
(43) Pub. Date: Feb. 8, 2024

(54) Apparatus, method and computer program for decoding neural network parameters and apparatus, method and computer program for encoding neural network parameters using an update model

(71) Applicant: Fraunhofer-Gesellschaft zur Foerderung der angewandten Forschung e.V., Munich (DE)

(72) Inventors: Paul HAASE, Berlin (DE); Heiner KIRCHHOFFER, Berlin (DE); Daniel BECKING, Berlin (DE); Gerhard TECH, Berlin (DE); Karsten MUELLER, Berlin (DE); Wojciech SAMEK, Berlin (DE); Heiko SCHWARZ, Berlin (DE); Detlev MARPE, Berlin (DE); Thomas WIEGAND, Berlin (DE)

(21) Appl. No.: 18/380,551

(22) Filed: Oct. 16, 2023

Related U.S. Application Data
(63) Continuation of application No. PCT/EP2022/060124, filed on Apr. 14, 2022.

(30) Foreign Application Priority Data
Apr. 16, 2021 (EP) 21169030.0

(51) Int. Cl. G06N 3/082

(52) U.S. Cl. CPC G06N 3/082

(57) ABSTRACT

Embodiments according to the invention comprise an apparatus for decoding neural network parameters, which define a neural network. The apparatus may, optionally, be configured to obtain, e.g. to decode, parameters of a base model, e.g. NB, of the neural network which define one or more layers, e.g. base layers, of the neural network. Furthermore, the apparatus is configured to decode an update model, e.g. NU1 to NUK, which defines a modification of one or more layers, e.g. base layers, of the neural network, and the apparatus is configured modify parameters of a base model of the neural network using the update model, in order to obtain an updated model, e.g. designated as “new model” comprising new model layers LNkj. Moreover, the apparatus is configured to evaluate a skip information, e.g. a skip_row_flag and/or a skip_column_flag, indicating whether a sequence, e.g. a row, or a column or a block, of parameters of the update model is zero or not.

### CROSS-REFERENCES TO RELATED APPLICATIONS

This application is a continuation of copending International Application No. PCT/EP2022/060124, filed Apr. 14, 2022, which is incorporated herein by reference in its entirety, and additionally claims priority from European Application No. EP 21 169 030.0, filed Apr. 16, 2021, which is incorporated herein by reference in its entirety.

Embodiments according to the invention are related to apparatuses, methods and computer programs for decoding neural network parameters and apparatuses, methods and computer programs for encoding neural network parameters using an update model.

Further embodiments according to the invention are related to methods for Entropy Coding of parameters of incremental updates of neural networks.

### BACKGROUND OF THE INVENTION

Neural networks, NN, are used in a wide variety of applications. With ever increasing computational power, NN with increasing complexity, and hence increasing numbers of neural network parameters, e.g. weights, may be used.

Especially computationally expensive training processes may be performed on dedicated training devices, such that updated neural network parameters may have to be transmitted from such a training device to end-user devices.

Furthermore, NN may be trained on a plurality of devices, e.g. a plurality of end-user devices, wherein it may be advantageous to provide an aggregated version of the plurality of training results. Therefore, respective training results may have to be transmitted for a subsequent aggregation and the aggregated updated parameter set may be retransmitted to each of the devices.

Therefore, there is a need for a concept for coding, e.g. encoding and/or decoding neural network parameters which makes a good compromise between an efficiency, a complexity and computational costs of the concept.

### SUMMARY

An embodiment may have an apparatus for decoding neural network parameters, which define a neural network, wherein the apparatus is configured to decode an update model which defines a modification of one or more layers of the neural network, and wherein the apparatus is configured modify parameters of a base model of the neural network using the update model, in order to acquire an updated model, and wherein the apparatus is configured to evaluate a skip information indicating whether a sequence of parameters of the update model is zero or not.

Another embodiment may have an apparatus for encoding neural network parameters, which define a neural network, wherein the apparatus is configured to encode an update model which defines a modification of one or more layers of the neural network, and wherein the apparatus is configured to provide the update model, such that the update model enables a decoder to modify parameters of a base model of the neural network using the update model, in order to acquire an updated model, and wherein the apparatus is configured to provide and/or determine a skip information indicating whether a sequence of parameters of the update model is zero or not.

Another embodiment may have a method for decoding neural network parameters, which define a neural network, the method comprising decoding an update model which defines a modification of one or more layers of the neural network, and modifying parameters of a base model of the neural network using the update model, in order to acquire an updated model, and evaluating a skip information indicating whether a sequence of parameters of the update model is zero or not.

Another embodiment may have a method for encoding neural network parameters, which define a neural network, the method comprising encoding an update model which defines a modification of one or more layers of the neural network, and providing the update model, in order to modify parameters of a base model of the neural network using the update model, in order to acquire an updated model, and providing and/or determining a skip information indicating whether a sequence of parameters of the update model is zero or not.

Another embodiment may have a non-transitory digital storage medium having a computer program stored thereon to perform the method for decoding neural network parameters, which define a neural network, the method comprising decoding an update model which defines a modification of one or more layers of the neural network, and modifying parameters of a base model of the neural network using the update model, in order to acquire an updated model, and evaluating a skip information indicating whether a sequence of parameters of the update model is zero or not, when said computer program is run by a computer.

Another embodiment may have a non-transitory digital storage medium having a computer program stored thereon to perform the method for encoding neural network parameters, which define a neural network, the method comprising encoding an update model which defines a modification of one or more layers of the neural network, and providing the update model, in order to modify parameters of a base model of the neural network using the update model, in order to acquire an updated model, and providing and/or determining a skip information indicating whether a sequence of parameters of the update model is zero or not, when said computer program is run by a computer.

Another embodiment may have an encoded representation of neural network parameters, comprising: an update model which defines a modification of one or more layers of the neural network, and a skip information indicating whether a sequence of parameters of the update model is zero or not.

Embodiments according to the invention comprise an apparatus for decoding neural network parameters, which define a neural network. The apparatus may, optionally, be configured to obtain, e.g. to decode, parameters of a base model, e.g. NB, of the neural network which define one or more layers, e.g. base layers, of the neural network.

Furthermore, the apparatus is configured to decode an update model, e.g. NU1 to NUK, which defines a modification of one or more layers, e.g. base layers, of the neural network, and the apparatus is configured modify parameters of a base model of the neural network using the update model, in order to obtain an updated model, e.g. designated as “new model” comprising new model layers LNkj.

Moreover, the apparatus is configured to evaluate a skip information, e.g. a skip_row_flag and/or a skip_column_flag, indicating whether a sequence, e.g. a row, or a column or a block, of parameters of the update model is zero or not.

The inventors have recognized that neural network parameters may be transmitted efficiently using a base model and an update model. In the training of neural networks, only a portion of neural network parameters may be changed significantly compared to base parameters, e.g. default or initial parameters. Hence, the inventors recognized that it may be advantageous to only transmit a change information, e.g. a modification information in the form of the update model. As an example, the base model may be stored in the decoder, such that a transmission may not be necessary. On the other hand, such a base model may for example be transmitted only once.

Furthermore, the inventors recognized that such an update model approach may be further improved by using a skip information. The skip information may comprise an information about a structure of the update model with regard to an information distribution within the model. Hence, the skip information may indicate that a certain sequence of update model parameters does not comprise an update information or in other words is zero. Hence, instead of such a parameter sequence, only the skip information may have to be transmitted.

Moreover an evaluation and application (e.g. to a base model) of such parameters may be skipped in the decoder, based on the skip information.

In addition, it is to be noted that base model and update model may address neural network parameters of whole neural networks, or of layers thereof, or of other subsets or portion of the neural network parameters of a neural network.

According to further embodiments of the invention, the update model describes differential values, and the apparatus is configured to additively or subtractively combine the differential values with values of parameters of the base model, in order to obtain, for example corresponding, values of parameters of the updated model.

The inventors recognized that an additive or subtractive modification information may allow an effective parameter update, as well as a computationally inexpensive parameter adaptation.

According to further embodiments of the invention, the apparatus is configured to combine differential values or differential tensors L_{Uk,j}, which are associated with a j-th layer of the neural network, with base value parameters or base value tensors L_{Bj}, which represent values of parameters of a j-th layer of a base model of the neural net, according to

L_{Nkj}=L_{Bj}+L_{Uk,j},for all j, or for all j for which the update model comprises a layer

In order to obtain updated model value parameters or updated model value tensors L_{Nkj}, which represent values of parameters of a j-th layer of an updated model having model index k of the neural network, wherein, for example, “+” may define an element-wise addition operation between two tensors.

The inventors recognized that neural network parameters may, for example, be represented efficiently using tensors. Furthermore, the inventors recognized that a combination of update and base information in the form of tensors may be performed in a computationally inexpensive manner.

According to further embodiments of the invention, the update model describes scaling factor values, and the apparatus is configured to scale values of parameters of the base model using the scaling factor values, in order to obtain, for example corresponding, values of parameters of the updated model.

The inventors recognized that using scaling factors may allow to represent a parameter update with few bits, such that such an information may be transmitted with few transmission resources. Furthermore, an application of a scaling factor may be performed with low computational costs.

According to further embodiments of the invention, the apparatus is configured to combine scaling values or scaling tensors L_{Uk,j}, which are associated with a j-th layer of the neural network, with base value parameters or base value tensors L_{Bj}, which represent values of parameters of a j-th layer of a base model of the neural net, according to

L_{Nk,j}=L_{Bj}·L_{Uk,j, for all j, or for all j for which the update model comprises a layer}

in order to obtain updated model value parameters or updated model value tensors L_{Nkj}, which represent values of parameters of a j-th layer of an updated model having model index k of the neural network, wherein, for example, “·” may define an element-wise multiplication operation between two tensors.

The inventors recognized that a combination of tensors and multiplicative scaling may allow an efficient neural network parameter updating.

According to further embodiments of the invention, the update model describes replacement values, and the apparatus is configured to replace values of parameters of the base model using the replacement values, in order to obtain, for example corresponding, values of parameters of the updated model.

The inventors recognized that, in some cases, it may be more efficient to replace a value of a base model with a value from an update model in order to represent a parameter update, e.g. instead of an additive or multiplicative modification.

According to further embodiments of the invention, the neural network parameters comprise weight values defining weights of neuron interconnections which emerge from a neuron or which lead towards a neuron.

Hence, weight values of NN may be decoded efficiently.

According to further embodiments of the invention, a sequence of neural network parameters comprises weight values which are associated with a row or column of a matrix, e.g. a 2-dimensional matrix or even a higher-dimensional matrix.

The inventors recognized that a row-wise or column-wise arrangement of a sequence of neural network parameters may allow an efficient processing, e.g. comprising a matrix scanning, of the sequence.

According to further embodiments of the invention, the skip information comprises a flag indicating, e.g. using a single bit, whether all parameters of a sequence, e.g. of a row, of parameters of the update model are zero or not.

The inventors recognized that a flag dedicated to a sequence of neural network parameters may allow an individual evaluation by the decoder on how to efficiently handle the corresponding sequence. As an example, in case the flag indicates that corresponding parameters of the update model are zero a processing of such a sequence may be skipped.

Hence, according to further embodiments of the invention, the apparatus is configured to selectively skip a decoding of a sequence, e.g. of a row, of parameters of the update model in dependence on the skip information.

According to further embodiments of the invention, the apparatus is configured to selectively set values of a sequence of parameters of the update model to a predetermined value, e.g. to zero, in dependence on the skip information.

As an example, instead of the sequence of parameters, only the skip information may be transmitted to the decoder. Based on the skip information, the decoder may conclude that neural network parameters of the sequence have predetermined values and may hence reconstruct these values.

According to further embodiments of the invention, the skip information comprises an array of skip flags indicating, e.g. using a single bit, whether all parameters of respective sequences, e.g. of a row, of parameters of the update model are zero or not, wherein, for example, each flag may be associated with one sequence of parameters of the update model.

The inventors recognized that using an array of skip flags may allow to provide a compact information addressing a plurality of sequences of neural network parameters of the update model.

Hence, according to further embodiments of the invention, the apparatus is configured to selectively skip a decoding of respective sequences (or e.g. of a respective sequence), e.g. of a row, of parameters of the update model in dependence on respective skip flags associated with respective sequences of parameters.

According to further embodiments of the invention, the apparatus is configured to evaluate, e.g. to decode and to use, an array size information, e.g. N, describing a number of entries of the array of skip flags. This may provide a good flexibility and good efficiency.

According to further embodiments of the invention, the apparatus is configured to decode one or more skip flags using a context model and the apparatus is configured to select a context model for a decoding of one or more skip flags in dependence on one or more previously decoded symbols, e.g. in dependence on one or more previously decoded skip flags.

The inventors recognized that using a context model may allow to efficiently encode and correspondingly decode skip flags.

According to further embodiments of the invention, the apparatus is configured to apply a single context model for a decoding of all skip flags associated with a layer of the neural network.

This may allow a simple decoding of skip flags with low computational effort.

According to further embodiments of the invention, the apparatus is configured to select a context model for a decoding of a skip flag, e.g. out of a set of two context models, in dependence on a previously decoded skip flag.

The inventors recognized that a correlation between corresponding skip flags may be exploited by a selection of a context model, for an increased coding efficiency.

According to further embodiments of the invention, the apparatus is configured to select a context model for a decoding of a skip flag, e.g. out of a set of two context models, in dependence on a value of a corresponding (e.g. co-located, e.g. associated with a corresponding sequence of parameters of an update model, which may, for example, be related to the same neural network parameters (for example defining the same neuron interconnections) to which the currently considered skip flag is related) skip flag in a previously decoded neural network model, e.g. a previously decoded update or a previously decoded base model.

The inventors recognized that for a decoding of a skip flag, a correlation with a corresponding skip flag of a previously decoded neural network may be exploited by selecting the context model accordingly.

According to further embodiments of the invention, the apparatus is configured to select a set of context models selectable for a decoding of a skip flag, e.g. out of a set of two context models, in dependence on a value of a corresponding (e.g. co-located, e.g. associated with a corresponding sequence of parameters of an update model, which may, for example, be related to the same neural network parameters (for example defining the same neuron interconnections) to which the currently considered skip flag is related) skip flag in a previously decoded neural network model, e.g. a previously decoded update model or a previously decoded base model.

The inventors recognized that, in order to improve coding efficiency, a set of context models may be used for decoding and accordingly encoding a skip flag. Furthermore, the inventors recognized that a correlation between a previously decoded neural network model and a currently decoded neural network model may be exploited for the selections of such a set of context models.

According to further embodiments of the invention, the apparatus is configured to select a set of context models selectable for a decoding of a skip flag, e.g. out of a set of two context models, in dependence on an existence of a corresponding layer in a previously decoded neural network model, e.g. a previously decoded update model or in a previously decoded base model, wherein it may optionally be possible that a previously decoded neural network model does not comprise a certain layer, but that this certain layer may be present in the currently considered layer. This may, for example, be the case if the topology of the neural network is changed, e.g. by adding a layer. This may, for example, also be the case if a certain layer of the neural network is not changed in a previous update, such that no information regarding this certain layer is included in the previous update.

As an example, the decoder may be configured to evaluate whether a correlation between corresponding skip flags is present. Lacking a corresponding layer may indicate that there are no skip flags in a previously decoded neural network model that may correspond to present, to be decoded, skip flags. Hence, this information may be used for the choice of the set of context models.

According to further embodiments of the invention, the apparatus is configured to select a context model out of the selected set of context models in dependence on one or more previously decoded symbols, e.g. in dependence on one or more previously decoded skip flags, of a currently decoded update model.

Hence, it is to be noted that, according to embodiments, several decisions and hence degrees of freedom may be incorporated. A correlation of information between a previously decoded neural network model and a currently decoded model, as well as between previously decoded symbols of the currently decoded update model and currently decoded symbols may be exploited. Hence, these correlations may be used to first select a set of context models, and then to select a context model out of the set of context models and therefore to decode a current symbol. The inventors recognized that, in simple words, several layers of information correlation may be exploited in order to improve coding efficiency.

Further embodiments according to the invention comprise an apparatus for decoding neural network parameters, which define a neural network. Optionally, The apparatus may be configured to obtain, e.g. decode, parameters of a base model, e.g. NB, of the neural network which define one or more layers, e.g. base layers, of the neural network.

Furthermore, the apparatus is configured to decode a current update model, e.g. NU1 or NUK, which defines a modification of one or more layers, e.g. base layers, of the neural network, e.g. of LB,j, or a modification of one or more intermediate layers or, e.g. of LUK-1,j, of the neural network

Moreover, the apparatus is configured modify parameters of a base model of the neural network, e.g. parameters of LB,j, or intermediate parameters, e.g. parameters of LUK-1,j, derived from the base model of the neural network using one or more intermediate update models, e.g. using NU1 to NUK-1, using the current update model, e.g. NU1 or NUK, in order to obtain an updated model, e.g. designated as “new model” comprising new model layers LN1,j or LNK,j.

In addition, the apparatus is configured to entropy-decode, e.g. using a Context-Adaptive Binary Arithmetic Coding, one or more parameters of the current update model, and the apparatus is configured to adapt a context used for an entropy-decoding of one or more parameters of the current update model in dependence on one or more previously decoded parameters of the base model and/or in dependence on one or more previously decoded parameters of an intermediate update model, e.g. in order to exploit a correlation between the current update model and the base model, and/or a correlation between the current update model and the intermediate update model.

The inventors recognized that a correlation between a previously decoded neural network model, for example the base model or an intermediate model, and a currently decoded neural network model, the current update model, may be exploited for the adaption of context models, used for entropy-decoding of one or more parameters of the current update model.

As an example, in iterative training procedures of neural networks, based on the base model (for example, comprising or being associated with default neural network parameters or initial neural network parameters), for example after each training, an updated, e.g. improved, model may be obtained. The inventors recognized that a modification or an alternation of neural network parameters, for example in between training cycles, may be correlated. There may be some sets of neural network parameters that may be correlated throughout preceding and following trainings. Hence, a coding efficiency may be improved by exploiting such a correlation. Intermediate models may, for example, represent updated neural networks between a base model, e.g. an initial model and a current model, e.g. associated with a most recent training cycle.

Therefore, the inventors recognized that an adaptation of a context for the decoding and correspondingly encoding may be advantageous, in order to incorporate an information about such a correlation.

According to further embodiments of the invention, the apparatus is configured to decode quantized and binarized representations of one or more parameters, e.g. a differential value LUk,j or a scaling factor value Luk,j or a replacement value Luk,j, of the current update model using a context-based entropy decoding.

The inventors recognized that usage of quantized and binarized representations for parameters of the current update model allows to further increase the coding efficiency of an inventive approaches. As an example, using binary representations may keep the complexity low and may allow a simple probability modelling for more frequently used bits of any symbol.

According to further embodiments of the invention, the apparatus is configured to entropy-decode at least one significance bin associated with a currently considered parameter value of the current update model, the significance bin describing whether a quantization index of the currently considered parameter value is equal to zero or not.

This may allow to save bits used for the encoding and/or decoding of a neural network parameters. If the significance bin indicates the parameter to be zero, further bins may not be necessary and may hence be used for other information.

According to further embodiments of the invention, the apparatus is configured to entropy-decode at least one sign bin associated with a currently considered parameter value of the current update model, the sign bin describing whether a quantization index of the currently considered parameter value is greater than zero or smaller than zero.

The inventors recognized that usage of a sign bin allow to provide a compact low complexity information about a sign of a parameter value.

According to further embodiments of the invention, the apparatus is configured to entropy-decode an unary sequence associated with a currently considered parameter value of the current update model, the bins of the unary sequence describing whether an absolute value of a quantization index of the currently considered parameter value is greater a respective bin weight, e.g. X, or not.

The inventors recognized that usage of such a unary sequence allows an efficient representation of a currently considered parameter value.

According to further embodiments of the invention, the apparatus is configured to entropy-decode one or more greater-than-X bins indicative of an absolute value of a quantization index of the currently considered parameter value being greater than X or not, wherein X is an integer greater than zero.

The inventors recognized that such a subsequent indication of intervals for the quantization index allows an efficient representation of its absolute value.

According to further embodiments of the invention, the apparatus is configured to select a context model for a decoding of one or more bins of a quantization index of the currently considered parameter value, e.g. out of a set of two context models, in dependence on a value of a previously decoded corresponding (e.g. co-located; e.g. associated with a corresponding sequence of parameters of an update model, which may, for example, be related to the same neural network parameters (for example defining the same neuron interconnections) to which the currently considered parameter value is related) parameter value in a previously decoded neural network model, e.g. a previously decoded update or a previously decoded base model, e.g. in a corresponding layer of a previously decoded base model or of a previously decoded update model.

The inventors recognized that a correlation between a currently decoded model and a previously decoded model may be exploited. The inventors recognized that such a correlation may be advantageously exploited, e.g. in order to provide an improved coding efficiency, by selecting a context model for decoding a quantization index of a currently considered parameter value in dependence on a value of a previously decoded corresponding parameter value in the previously decoded neural network model. The inventors recognized that a correlation of corresponding quantization indices, e.g. of a corresponding parameter values of subsequent neural network trainings, may be incorporated in the selection of the context model.

According to further embodiments of the invention, the apparatus is configured to select a set of context models selectable for a decoding of one or more bins of a quantization index of the currently considered parameter value, e.g. out of a set of two context models, in dependence on a value of a previously decoded corresponding (e.g. co-located; e.g. associated with a corresponding sequence of parameters of an update model, which may, for example, be related to the same neural network parameters (for example defining the same neuron interconnections) to which the currently considered parameter value is related) parameter value, e.g. a “corresponding” parameter value related to, or defining, a same neuron interconnection between two given neurons like the currently considered parameter value, in a previously decoded neural network model, e.g. a previously decoded update or a previously decoded base model, e.g. in a corresponding layer of a previously decoded base model or of a previously decoded update model.

The inventors recognized, that a correlation between a currently decoded model and a previously decoded model may, for example, further be exploited, e.g. for an increased coding efficiency, for a selection of a set of context models, hence as an example, a plurality of context models, for bins of quantization indices. Usage of a whole set of context models may allow to implement another degree of freedom allowing a better context selection and hence increased coding efficiency.

According to further embodiments of the invention, the apparatus is configured to select a context model for a decoding of one or more bins of a quantization index of the currently considered parameter value in dependence on an absolute value of a previously decoded corresponding parameter value in a previously decoded neural network model.

Alternatively, the apparatus is configured to select a set of context models for a decoding of one or more bins of a quantization index of the currently considered parameter value in dependence on an absolute value of a previously decoded corresponding parameter value in a previously decoded neural network model.

The inventors recognized that a correlation of information may optionally be exploited based on absolute values of previously decoded corresponding parameter values in a previously decoded neural network model. Therefore, a context model or a set of context model may be chosen, wherein the chosen set or context model may comprise a context, well or for example best, representing an correlation of the bins of the quantization indices based on the corresponding previously decoded absolute value.

According to further embodiments of the invention, the apparatus is configured to compare a previously decoded corresponding parameter value in a previously decoded neural network model with one or more threshold values, e.g. T1, T2, etc.

Furthermore, the apparatus is configured to select a context model for a decoding of one or more bins of a quantization index of the currently considered parameter value in dependence on a result of the comparison.

Alternatively, the apparatus is configured to select a set of context models for a decoding of one or more bins of a quantization index of the currently considered parameter value in dependence on a result of the comparison, e.g. such that a first set is chosen if the corresponding or co-located parameter is lower than a first threshold T1, e.g. such that a second set is chosen if the corresponding or co-located parameter is greater than or equal to the first threshold T1, and e.g. such that a third set is chosen if the corresponding or co-located parameter is greater than or equal to a threshold T2.

The inventors recognized that threshold values may allow an computationally inexpensive way of selecting a context model or a set of context models. Using a plurality of thresholds may, for example, allow to provide a differentiated information on what context model or set of context models to choose or to select.

According to further embodiments of the invention, the apparatus is configured compare a previously decoded corresponding parameter value in a previously decoded neural network model with a single threshold value, (or a single threshold values), e.g. T1.

Furthermore, the apparatus is configured to select a context model for a decoding of one or more bins of a quantization index of the currently considered parameter value in dependence on a result of the comparison with the single threshold value.

Alternatively, the apparatus is configured to select a set of context models for a decoding of one or more bins of a quantization index of the currently considered parameter value in dependence on a result of the comparison with the single threshold value.

The inventors recognized that usage of a single threshold may allow to provide a good compromise between an amount of information extracted from or used based on the previously decoded corresponding parameter value and computational costs.

According to further embodiments of the invention, the apparatus is configured compare an absolute value of a previously decoded corresponding parameter value in a previously decoded neural network model with one or more threshold values, e.g. T1, T2, etc.

Furthermore, the apparatus is configured to select a context model for a decoding of one or more bins of a quantization index of the currently considered parameter value in dependence on a result of the comparison.

Alternatively, the apparatus is configured to select a set of context models for a decoding of one or more bins of a quantization index of the currently considered parameter value in dependence on a result of the comparison, e.g. such that a first set is chosen if the corresponding or co-located parameter is lower than a first threshold T1, e.g. such that a second set is chosen if the corresponding or co-located parameter is greater than or equal to the first threshold T1, and e.g. such that a third set is chosen if the corresponding or co-located parameter is greater than or equal to a threshold T2.

The inventors recognized that, based on a computationally inexpensive comparison of an absolute value of a previously decoded corresponding parameter value with one or more threshold values, a sophisticated choice of the context model or set of context models may be performed.

According to further embodiments of the invention, the apparatus is configured to entropy-decode at least one significance bin associated with a currently considered parameter value of the current update model, the significance bin describing whether a quantization index of the currently considered parameter value is equal to zero or not, and to select a context for the entropy-decoding of the at least one significance bin, or a set of contexts for the entropy-decoding of the at least one significance bin, in dependence on a value, e.g. an absolute value or a signed value, of a previously decoded corresponding (e.g. co-located; e.g. associated with a corresponding sequence of parameters of an update model, which may, for example, be related to the same neural network parameters (defining the same neuron interconnections) to which the currently considered parameter value is related) parameter value, e.g. a “corresponding” parameter value related to, or defining, a same neuron interconnection between two given neurons like the currently considered parameter value, in a previously decoded neural network model, wherein, for example, the corresponding parameter value is compared with a single threshold value in order to select the context or in order to select a set of contexts, or wherein for example, the corresponding parameter value is compared with two threshold values, e.g. T₁=1 and T₂=2.

The inventors recognized that usage of a significance bin may allow to improve coding efficiency. In case a parameter value is zero, just the significance bin may have to be transmitted for an indication thereof. Therefore, for example, for update models, comprising only some change values for a fraction of neural network parameters of a base model or of an intermediate model, significance bins may allow to reduce an amount of bits that may need to be transmitted, in order to represent the update model. Furthermore, the significance bin may be encoded and hence decoded effectively using a context model, wherein the inventors recognized that a selection of the context may be performed based on a corresponding previously decoded parameter value in a previously decoded neural network model in order to exploit a correlation between the current update model and the previously decoded model.

According to further embodiments of the invention, the apparatus is configured to entropy-decode at least one sign bin associated with a currently considered parameter value of the current update model, the sign bin describing whether a quantization index of the currently considered parameter value is greater than zero or smaller than zero, and to select a context for the entropy-decoding of the at least one sign bin, or a set of contexts for the entropy-decoding of the at least one sign bin, in dependence on a value of a previously decoded corresponding (e.g. co-located; e.g. associated with a corresponding sequence of parameters of an update model, which are related to the same neural network parameters (defining the same neuron interconnections) to which the currently considered parameter value is related) parameter value, e.g. a “corresponding” parameter value related to, or defining, a same neuron interconnection between two given neurons like the currently considered parameter value, in a previously decoded neural network model, wherein, for example, the corresponding parameter value is compared with a single threshold value in order to select the context or in order to select a set of contexts; or wherein for example, the corresponding parameter value is compared with two threshold values, e.g. T1=0 and T2=1.

As explained before, inventors recognized that usage of a sign bin may, for example, allow to provide a compact, low complexity information about a sign of a parameter value. Furthermore, the sign bin may, for example, be encoded and hence decoded effectively using a context model, wherein the inventors recognized that a selection of the context may be performed based on a parameter value in a previously decoded neural network model, e.g. in order to exploit a correlation between the current update model and the previously decoded model.

According to further embodiments of the invention, the apparatus is configured to entropy-decode one or more greater-than-X bins indicative of an absolute value of a quantization index of the currently considered parameter value being greater than X or not, wherein X is an integer greater than zero, and to select a context for the entropy-decoding of the at least one greater-than-X bin, or a set of a contexts for the entropy-decoding of the at least one greater-than-X bin, in dependence on a value, e.g. an absolute value or a signed value, of a previously decoded corresponding (e.g. co-located; e.g. associated with a corresponding sequence of parameters of an update model, which are related to the same neural network parameters (defining the same neuron interconnections) to which the currently considered parameter value is related) parameter value, e.g. a “corresponding” parameter value related to, or defining, a same neuron interconnection between two given neurons like the currently considered parameter value) in a previously decoded neural network model, wherein, for example, the corresponding parameter value is compared with a single threshold value in order to select the context or in order to select a set of contexts, e.g. T1=X.

As explained before, the inventors recognized that such a subsequent indication of intervals for the quantization index allows an efficient representation of its absolute value. Furthermore, the greater-than-X bins may be encoded and hence decoded effectively using context models, wherein the inventors recognized that a selection of the contexts may be performed based on a previously decoded corresponding parameter value in a previously decoded neural network model, e.g. in order to exploit a correlation between the current update model and the previously decoded model.

According to further embodiments of the invention, the apparatus is configured to choose a context model out of a selected set of context models in dependence on one or more previously decoded bins or parameters of the current update model (or, for example, in dependence on the current update model).

The inventors recognized that a correlation of parameters or bins within the current update model may be exploited, e.g. as well, for example in order to select or to choose a context model for an efficient encoding and respectively decoding.

Further embodiments according to the invention comprise an apparatus for encoding neural network parameters, which define a neural network. The apparatus may optionally, be configured to obtain and/or provide, e.g. encode, parameters of a base model, e.g. NB, of the neural network which define one or more layers, e.g. base layers, of the neural network.

Furthermore, the apparatus is configured to encode an update model, e.g. NU1 to NUK, which defines a modification of one or more layers, e.g. base layers, of the neural network. Moreover, e.g., the apparatus is configured to provide the update model, e.g., such that the update model enables a decoder, e.g. an apparatus for decoding, as defined above, to modify parameters of a base model of the neural network using the update model, in order to obtain an updated model, e.g. designated as “new model” comprising new model layers LNkj.

Moreover, the apparatus is configured to provide and/or determine, and/or encode, a skip information, e.g. a skip_row_flag and/or a skip_column_flag, indicating whether a sequence, e.g. a row, or a column or a block, of parameters of the update model is zero or not.

The encoder as described above may be based on the same considerations as the above-described decoders. The encoder can, by the way, be completed with all (e.g. with all corresponding or all analogous) features and functionalities, which are also described with regard to the decoders.

According to further embodiments of the invention, the update model describes differential values, which enable a decoder to additively or subtractively combine the differential values with values of parameters of the base model, in order to obtain, e.g. corresponding, values of parameters of the updated model.

According to further embodiments of the invention, the apparatus is configured to determine the differential values as, or using, a difference between values of parameters of the updated model and, for example, corresponding, values of parameters of the base model.

According to further embodiments of the invention, the apparatus is configured to determine the differential values or differential tensors L_{Uk,j}, which are associated with a j-th layer of the neural network, such that a combination of the differential values or differential tensors L_{Uk,j}, with base value parameters or base value tensors L_{Bj}, which represent values of parameters of a j-th layer of a base model of the neural net, according to
L_{Nkj}=L_{Bj}+L_{Uk,j}, for all j, or for all j for which the update model comprises a layer
   allows for a determination of updated model value parameters or updated model value tensors L_{Nkj}, which represent values of parameters of a j-th layer of the updated model having model index k of the neural network, wherein, for example, “+” may define an element-wise addition operation between two tensors.

According to further embodiments of the invention, the update model describes scaling factor values, wherein the apparatus is configured to provide the scaling factor values such that a scaling of values of parameters of the base model using the scaling factor values, results in, e.g. corresponding, values of parameters of the updated model.

According to further embodiments of the invention, the apparatus is configured to determine the scaling factor values as a scaling factor between values of parameters of the updated model and, e.g. corresponding, values of parameters of the base model.

According to further embodiments of the invention, the apparatus is configured to determine the scaling values or scaling tensors L_{Uk,j}, which are associated with a j-th layer of the neural network, such that a combination of the scaling values or scaling tensors with base value parameters or base value tensors L_{Bj}, which represent values of parameters of a j-th layer of a base model of the neural net, according to
L_{Nk,j}=L_{Bj}·L_{Uk,j}, for all j, or for all j for which the update model comprises a layer
   allows for a determination of updated model value parameters or updated model value tensors L_{Nkj}, which represent parameters of a j-th layer of an updated model having model index k of the neural network, wherein, for example, “:” may define an element-wise division operation between two tensors.

According to further embodiments of the invention, the update model describes replacement values, wherein the apparatus is configured to provide the replacement values such that a replacement of values of parameters of the base model using the replacement values, allows to obtain, e.g. corresponding, values of parameters of the updated model.

According to further embodiments of the invention, the apparatus is configured to determine the replacement values.

According to further embodiments of the invention, the neural network parameters comprise weight values defining weights of neuron interconnections which emerge from a neuron or which lead towards a neuron.

According to further embodiments of the invention, a sequence of neural network parameters comprises weight values which are associated with a row or column of a matrix, e.g. a 2-dimensional matrix or even a higher-dimensional matrix.

According to further embodiments of the invention, the skip information comprises a flag indicating, e.g. using a single bit, whether all parameters of a sequence, e.g. of a row, of parameters of the update model are zero or not.

According to further embodiments of the invention, the apparatus is configured to provide the skip information to signal a skipping of a decoding of a sequence, e.g. of a row, of parameters of the update model.

According to further embodiments of the invention, the apparatus is configured to provide a skip information comprising an information whether a sequence of parameters of the update model have a predetermined value, e.g. zero.

According to further embodiments of the invention, the skip information comprises an array of skip flags indicating, e.g. using a single bit, whether all parameters of respective sequences, e.g. of a row, of parameters of the update model are zero or not, wherein, for example, each flag may be associated with one sequence of parameters of the update model.

According to further embodiments of the invention, the apparatus is configured to provide skip flags associated with respective sequences of parameters to signal a skipping of a decoding of a respective sequences, e.g. of a row, of parameters of the update model.

According to further embodiments of the invention, the apparatus is configured to provide, e.g. to encode and/or to determine, an array size information, e.g. N, describing a number of entries of the array of skip flags.

According to further embodiments of the invention, the apparatus is configured to encode one or more skip flags using a context model; and the apparatus is configured to select a context model for an encoding of one or more skip flags in dependence on one or more previously encoded symbols, e.g. in dependence on one or more previously encoded skip flags.

According to further embodiments of the invention, the apparatus is configured to apply a single context model for an encoding of all skip flags associated with a layer of the neural network.

According to further embodiments of the invention, the apparatus is configured to select a context model for an encoding of a skip flag, e.g. out of a set of two context models, in dependence on a previously encoded skip flag.

According to further embodiments of the invention, the apparatus is configured to select a context model for an encoding of a skip flag, e.g. out of a set of two context models, in dependence on a value of a corresponding (e.g. co-located; e.g. associated with a corresponding sequence of parameters of an update model, which may for example be related to the same neural network parameters (defining the same neuron interconnections) to which the currently considered skip flag is related) skip flag in a previously encoded neural network model, e.g. a previously encoded update or a previously encoded base model.

According to further embodiments of the invention, the apparatus is configured to select a set of context models selectable for an encoding of a skip flag, e.g. out of a set of two context models, in dependence on a value of a corresponding (e.g. co-located; e.g. associated with a corresponding sequence of parameters of an update model, which may for example be related to the same neural network parameters (defining the same neuron interconnections) to which the currently considered skip flag is related, skip flag in a previously encoded neural network model, e.g. a previously encoded update model or a previously encoded base model.

According to further embodiments of the invention, the apparatus is configured to select a set of context models selectable for an encoding of a skip flag, e.g. out of a set of two context models, in dependence on an existence of a corresponding layer in a previously encoded neural network model, e.g. a previously encoded update model or in a previously encoded base model, wherein it may, for example, be possible that a previously encoded neural network model does not comprise a certain layer, but that this certain layer is present in the currently considered layer. This may, for example, be the case if the topology of the neural network is changed, e.g. by adding a layer. This may also be the case if a certain layer of the neural network is not changed in a previous update, such that no information regarding this certain layer is included in the previous update.

According to further embodiments of the invention, the apparatus is configured to select a context model out of the selected set of context models in dependence on one or more previously encoded symbols, e.g. in dependence on one or more previously encoded skip flags, of a currently encoded update model.

Further embodiments according to the invention comprise an apparatus for encoding neural network parameters, which define a neural network. Optionally, the apparatus may be configured to obtain and/or provide, e.g. encode, parameters of a base model, e.g. NB, of the neural network which define one or more layers, e.g. base layers, of the neural network.

Furthermore, the apparatus is configured to encode a current update model, e.g. NU1 or NUK, which defines a modification of one or more layers, e.g. base layers, of the neural network, e.g. of LB,j, or a modification of one or more intermediate layers or, e.g. of LUK-1,j, of the neural network

Moreover, e.g., the apparatus is configured to provide the update model, e.g., such that the update model enables a decoder, e.g. an apparatus for decoding, as defined above, to modify parameters of a base model of the neural network, e.g. parameters of LB,j, or intermediate parameters, e.g. parameters of LUK-1,j derived from the base model of the neural network using one or more intermediate update models, e.g. using NU1 to NUK-1, using the current update model, e.g. NU1 or NUK, in order to obtain an updated model, e.g. designated as “new model” comprising new model layers LN1,j or LNK,j.

In addition, the apparatus is configured to entropy-encode, e.g. using a Context-Adaptive Binary Arithmetic Coding, one or more parameters of the current update model; wherein the apparatus is configured to adapt a context used for an entropy-encoding of one or more parameters of the current update model in dependence on one or more previously encoded parameters of the base model and/or in dependence on one or (e.g. more) previously encoded parameters of an intermediate update model, e.g. in order to exploit a correlation between the current update model and the base model, and/or a correlation between the current update model and the intermediate update model.

The encoder as described above may be based on the same considerations as the above-described decoders. The encoder can, by the way, be completed with all (e.g. with all corresponding or all analogous) features and functionalities, which are also described with regard to the decoders.

According to further embodiments of the invention, the apparatus is configured to encode quantized and binarized representations of one or more parameters, e.g. a differential value LUk,j or a scaling factor value Luk,j or a replacement value Luk,j, of the current update model using a context-based entropy encoding.

According to further embodiments of the invention, the apparatus is configured to entropy-encode at least one significance bin associated with a currently considered parameter value of the current update model, the significance bin describing whether a quantization index of the currently considered parameter value is equal to zero or not.

According to further embodiments of the invention, the apparatus is configured to entropy-encode at least one sign bin associated with a currently considered parameter value of the current update model, the sign bin describing whether a quantization index of the currently considered parameter value is greater than zero or smaller than zero.

According to further embodiments of the invention, the apparatus is configured to entropy-encode a unary sequence associated with a currently considered parameter value of the current update model, the bins of the unary sequence describing whether an absolute value of a quantization index of the currently considered parameter value is greater a respective bin weight, e.g. X, or not.

According to further embodiments of the invention, the apparatus is configured to entropy-encode one or more greater-than-X bins indicative of an absolute value of a quantization index of the currently considered parameter value being greater than X or not, wherein X is an integer greater than zero.

According to further embodiments of the invention, the apparatus is configured to select a context model for an encoding of one or more bins of a quantization index of the currently considered parameter value, e.g. out of a set of two context models, in dependence on a value of a previously encoded corresponding (e.g. co-located; e.g. associated with a corresponding sequence of parameters of an update model, which are related to the same neural network parameters (defining the same neuron interconnections) to which the currently considered parameter value is related) parameter value in a previously encoded neural network model, e.g. a previously encoded update or a previously encoded base model][e.g. in a corresponding layer of a previously encoded base model or of a previously encoded update model.

According to further embodiments of the invention, the apparatus is configured to select a set of context models selectable for an encoding of one or more bins of a quantization index of the currently considered parameter value, e.g. out of a set of two context models, in dependence on a value of a previously encoded corresponding (e.g. co-located; e.g. associated with a corresponding sequence of parameters of an update model, which are related to the same neural network parameters (defining the same neuron interconnections) to which the currently considered parameter value is related) parameter value, e.g. a “corresponding” parameter value related to, or defining, a same neuron interconnection between two given neurons like the currently considered parameter value) in a previously encoded neural network model, e.g. a previously encoded update or a previously encoded base model, e.g. in a corresponding layer of a previously encoded base model or of a previously encoded update model).

According to further embodiments of the invention, the apparatus is configured to select a context model for an encoding of one or more bins of a quantization index of the currently considered parameter value in dependence on an absolute value of a previously encoded corresponding parameter value in a previously encoded neural network model.

Alternatively, the apparatus is configured to select a set of context models for an encoding of one or more bins of a quantization index of the currently considered parameter value in dependence on an absolute value of a previously encoded corresponding parameter value in a previously encoded neural network model.

According to further embodiments of the invention, the apparatus is configured compare a previously encoded corresponding parameter value in a previously encoded neural network model with one or more threshold values, e.g. T1, T2, etc., and the apparatus is configured to select a context model for an encoding of one or more bins of a quantization index of the currently considered parameter value in dependence on a result of the comparison.

Alternatively, the apparatus is configured to select a set of context models for an encoding of one or more bins of a quantization index of the currently considered parameter value in dependence on a result of the comparison, e.g. such that a first set is chosen if the corresponding or co-located parameter is lower than a first threshold T1, e.g. such that a second set is chosen if the corresponding or co-located parameter is greater than or equal to the first threshold T1, and e.g. such that a third set is chosen if the corresponding or co-located parameter is greater than or equal to a threshold T2.

According to further embodiments of the invention, the apparatus is configured compare a previously encoded corresponding parameter value in a previously encoded neural network model with a single threshold values, e.g. T1.

Furthermore, the apparatus is configured to select a context model for an encoding of one or more bins of a quantization index of the currently considered parameter value in dependence on a result of the comparison with the single threshold value.

Alternatively, the apparatus is configured to select a set of context models for an encoding of one or more bins of a quantization index of the currently considered parameter value in dependence on a result of the comparison with the single threshold value.

According to further embodiments of the invention, the apparatus is configured compare an absolute value of a previously encoded corresponding parameter value in a previously encoded neural network model with one or more threshold values, e.g. T1, T2, etc.

Furthermore, the apparatus is configured to select a context model for an encoding of one or more bins of a quantization index of the currently considered parameter value in dependence on a result of the comparison.

Alternatively, the apparatus is configured to select a set of context models for an encoding of one or more bins of a quantization index of the currently considered parameter value in dependence on a result of the comparison, e.g. such that a first set is chosen if the corresponding or co-located parameter is lower than a first threshold T1, e.g. such that a second set is chosen if the corresponding or co-located parameter is greater than or equal to the first threshold T1, and e.g. such that a third set is chosen if the corresponding or co-located parameter is greater than or equal to a threshold T2.

According to further embodiments of the invention, the apparatus is configured to entropy-encode at least one significance bin associated with a currently considered parameter value of the current update model, the significance bin describing whether a quantization index of the currently considered parameter value is equal to zero or not, and to select a context for the entropy-encoding of the at least one significance bin, or a set of contexts for the entropy-encoding of the at least one significance bin, in dependence on a value, e.g. an absolute value or a signed value, of a previously encoded corresponding (e.g. co-located; e.g. associated with a corresponding sequence of parameters of an update model, which may for example be related to the same neural network parameters (e.g. defining the same neuron interconnections) to which the currently considered parameter value is related) parameter value, e.g. a “corresponding” parameter value related to, or defining, a same neuron interconnection between two given neurons like the currently considered parameter value, in a previously encoded neural network model, wherein, for example, the corresponding parameter value is compared with a single threshold value in order to select the context or in order to select a set of contexts; or wherein for example, the corresponding parameter value is compared with two threshold values, e.g. T₁=1 and T₂=2.

According to further embodiments of the invention, the apparatus is configured to entropy-encode at least one sign bin associated with a currently considered parameter value of the current update model, the sign bin describing whether a quantization index of the currently considered parameter value is greater than zero or smaller than zero, and to select a context for the entropy-encoding of the at least one sign bin, or a set of contexts for the entropy-encoding of the at least one sign bin, in dependence on a value of a previously encoded corresponding (e.g. co-located; e.g. associated with a corresponding sequence of parameters of an update model, which may, for example, be related to the same neural network parameters (e.g. defining the same neuron interconnections) to which the currently considered parameter value is related) parameter value, e.g. a “corresponding” parameter value related to, or defining, a same neuron interconnection between two given neurons like the currently considered parameter value, in a previously encoded neural network model, wherein, for example, the corresponding parameter value is compared with a single threshold value in order to select the context or in order to select a set of contexts; or wherein for example, the corresponding parameter value is compared with two threshold values, e.g. T1=0 and T2=1.

According to further embodiments of the invention, the apparatus is configured to Entropy-encode one or more greater-than-X bins indicative of an absolute value of a quantization index of the currently considered parameter value being greater than X or not, wherein X is an integer greater than zero, and to select a context for the entropy-encoding of the at least one greater-than-X bin, or a set of a contexts for the entropy-encoding of the at least one greater-than-X bin, in dependence on a value, e.g. an absolute value or a signed value, of a previously encoded corresponding, (e.g. co-located; e.g. associated with a corresponding sequence of parameters of an update model, which are related to the same neural network parameters (e.g. defining the same neuron interconnections) to which the currently considered parameter value is related), parameter value, e.g. a “corresponding” parameter value related to, or defining, a same neuron interconnection between two given neurons like the currently considered parameter value, in a previously encoded neural network model, wherein, for example, the corresponding parameter value is compared with a single threshold value in order to select the context or in order to select a set of contexts, e.g. T1=X.

According to further embodiments of the invention, the apparatus is configured to choose a context model out of a selected set of context models in dependence on one or more previously encoded bins or parameters (e.g. of the current update model) or the current update model.

Further embodiments according to the invention comprise a method for decoding neural network parameters, which define a neural network, the method optionally comprising obtaining, e.g. decoding, parameters of a base model, e.g. NB, of the neural network which define one or more layers, e.g. base layers, of the neural network. Furthermore, the method comprises decoding an update model, e.g. NU1 to NUK, which defines a modification of one or more layers, e.g. base layers, of the neural network, and modifying parameters of a base model of the neural network using the update model, in order to obtain an updated model, e.g. designated as “new model” comprising new model layers LNkj, and evaluating a skip information, e.g. a skip_row_flag and/or a skip_column_flag, indicating whether a sequence, e.g. a row, or a column or a block, of parameters of the update model is zero or not.

Further embodiments according to the invention comprise a method for decoding neural network parameters, which define a neural network, the method optionally comprising obtaining, e.g. decoding, parameters of a base model, e.g. NB, of the neural network which define one or more layers, e.g. base layers, of the neural network. Furthermore, the method comprises decoding a current update model, e.g. NU1 or NUK, which defines a modification of one or more layers, e.g. base layers, of the neural network, e.g. of LB,j, or a modification of one or more intermediate layers or, e.g of LUK-1,j, of the neural network, and modifying parameters of a base model of the neural network, e.g. parameters of LB,j, or intermediate parameters, e.g. parameters of LUK-1,j, derived from the base model of the neural network using one or more intermediate update models, e.g. using NU1 to NUK-1, using the current update model, e.g. NU1 or NUK, in order to obtain an updated model, e.g. designated as “new model” comprising new model layers LN1,j or LNK,j.

Moreover, the method comprises entropy-decoding, e.g. using a Context-Adaptive Binary Arithmetic Coding one or more parameters of the current update model and adapting a context used for an entropy-decoding of one or more parameters of the current update model in dependence on one or more previously decoded parameters of the base model and/or in dependence on one or previously decoded parameters of an intermediate update model, e.g. in order to exploit a correlation between the current update model and the base model, and/or a correlation between the current update model and the intermediate update model.

Further embodiments according to the invention comprise a method for encoding neural network parameters, which define a neural network, the method optionally comprising, obtaining and/or providing, e.g. encoding, parameters of a base model, e.g. NB, of the neural network which define one or more layers, e.g. base layers, of the neural network.

Furthermore, the method comprises encoding an update model, e.g. NU1 to NUK, which defines a modification of one or more layers, e.g. base layers, of the neural network, and providing the update model, in order to modify parameters of a base model of the neural network using the update model, in order to obtain an updated model, e.g. designated as “new model” comprising new model layers LNkj.

Moreover, the method comprises providing and/or determining, and/or encoding, a skip information, e.g. a skip_row_flag and/or a skip_column_flag, indicating whether a sequence, e.g. a row, or a column or a block, of parameters of the update model is zero or not.

Further embodiments according to the invention comprise a method for encoding neural network parameters, which define a neural network, the method optionally comprising obtaining and/or providing, e.g. encoding, parameters of a base model, e.g. NB, of the neural network which define one or more layers, e.g. base layers, of the neural network.

Furthermore, the method comprises encoding a current update model, e.g. NU1 or NUK, which defines a modification of one or more layers, e.g. base layers, of the neural network, e.g. of LB,j, or a modification of one or more intermediate layers or, e.g. of LUK-1,j, of the neural network, in order to modify parameters of a base model of the neural network, e.g. parameters of LB,j, or intermediate parameters, e.g. parameters of LUK-1,j, derived from the base model of the neural network using one or more intermediate update models, e.g. using NU1 to NUK-1, using the current update model, e.g. NU1 or NUK, in order to obtain an updated model, e.g. designated as “new model” comprising new model layers LN1,j or LNK,j.

Moreover, the method comprises entropy-encoding, e.g. using a Context-Adaptive Binary Arithmetic Coding, one or more parameters of the current update model and adapting a context used for an entropy-encoding of one or more parameters of the current update model in dependence on one or more previously encoded parameters of the base model and/or in dependence on one or previously encoded parameters of an intermediate update model, e.g. in order to exploit a correlation between the current update model and the base model, and/or a correlation between the current update model and the intermediate update model.

It is to be noted, that the methods as described above may be based on the same considerations as the above-described decoders and encoders. The methods can, by the way, be completed with all (e.g. with all corresponding or all analogous) features and functionalities, which are also described with regard to decoders and encoders.

Further embodiments according to the invention comprise a computer program for performing any of the above methods as disclosed herein, when the computer program runs on a computer.

Further embodiments according to the invention comprise an encoded representation of neural network parameters, e.g. a bitstream, comprising an update model, e.g. NU1 to NUK, which defines a modification of one or more layers, e.g. base layers, of the neural network, and a skip information, e.g. a skip_row_flag and/or a skip_column_flag, indicating whether a sequence, e.g. a row, or a column or a block, of parameters of the update model is zero or not.

### BRIEF DESCRIPTION OF THE DRAWINGS

Embodiments of the present invention will be detailed subsequently referring to the appended drawings, in which:

FIG. 1 shows a schematic view of an apparatus for encoding neural network parameters and of an apparatus for decoding neural network parameters, according to embodiments of the invention;

FIG. 2 shows a schematic view of a second apparatus for encoding neural network parameters and of a second apparatus for decoding neural network parameters, according to embodiments of the invention;

FIG. 3 shows a method for decoding neural network parameters, which define a neural network, according to embodiments of the invention;

FIG. 4 shows a method for decoding neural network parameters, which define a neural network, according to embodiments of the invention;

FIG. 5 shows a method for encoding neural network parameters, which define a neural network, according to embodiments of the invention;

FIG. 6 shows a method for encoding neural network parameters, which define a neural network, according to embodiments of the invention;

FIG. 7 shows an example of a graph representation of a feed forward neural network, e.g. a feed forward neural network, according to embodiments of the invention;

FIG. 8 shows an example of an illustration of uniform reconstruction quantizer, according to embodiments of the invention;

FIGS. 9a-b shows an example for location of admissible reconstruction vectors, according to embodiments of the invention;

FIG. 10 shows an example for a splitting of the sets of reconstruction levels into two subsets, according to embodiments of the invention; and

FIG. 11 shows an advantageous example of a state transition table for a configuration with 8 states.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may be combined with each other, unless specifically noted otherwise.

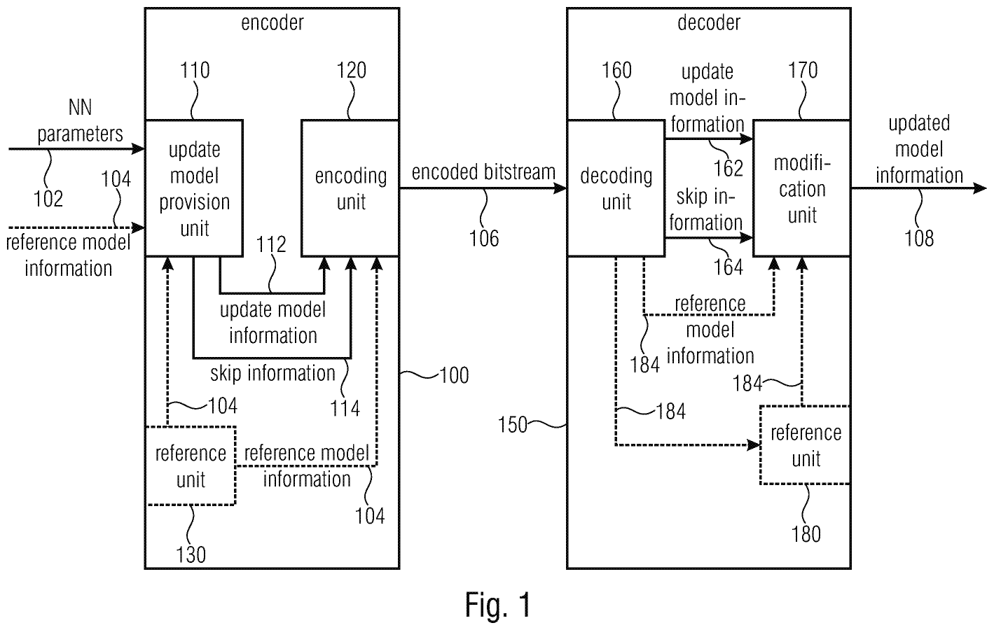

FIG. 1 shows a schematic view of an apparatus for encoding neural network parameters and of an apparatus for decoding neural network parameters, according to embodiments of the invention.

FIG. 1 shows an apparatus 100 for encoding neural network, NN, parameters, which define a neural network. Apparatus 100 comprises an update model provision unit 110 and an encoding unit 120.

For brevity, apparatus 100 for encoding will be referred to as encoder 100. As an optional feature, encoder 100, for example update model provision unit 110, may be provided with NN parameters 102.

Based thereon, the update model provision unit 110 may be configured to provide an update model information 112, being or comprising an update model, such that the update model enables a decoder 150 to modify parameters of a base model of the neural network using the update model, in order to obtain an updated model. As an example, the updated model may be associated with or represented by the NN parameters 102.

Alternatively, as an example, encoder 100 may be provided with an update model, e.g. in the form of an update model information 112, e.g. instead of NN parameters 102, hence being configured to encode the received update model, such that the update model enables the decoder 150 to modify parameters of the base model using the update model, in order to obtain the updated model, e.g. 108.

The update model information 112 is provided to the encoding unit 120 which is configured to encode the update model. The update model may define a modification of one or more layers of the neural network.

As an optional feature, encoder 100, e.g. update model provision unit 110, may be provided with a reference model information 104. As another optional feature, e.g. alternatively, encoder 100 may comprise a reference unit 130, configured to provide the reference model information 104 optionally to the update model provision unit 110 and/or to the encoding unit 120.

The reference model information 104 may comprise an information about the base model of the neural network, for example neural network parameters of the base model, which define one or more layers of the neural network. Hence, as an optional feature, encoder 100 may, for example, be configured to obtain, e.g. using update model provision unit 110 and/or e.g. using reference unit 130 the reference model information 104.

As an example, based on the reference model information 104, update model provision unit 110 may, for example, determine a difference between the base model and a model associated with the neural network parameters 102, e.g. between the base model and an update model provided to the encoder 100, for example between neural network parameters of the base model, e.g. represented by the reference model information, and corresponding NN parameters 102, e.g. of an updated version of the base model, e.g. of an updated model. This difference or differential information may be provided in the form of the update model information 112, e.g. as an update model.

As another example, e.g. instead of NN parameters 102, update model provision unit 110 may be configured to receive an updated model information, e.g. 108 or equivalent to 108, and the update model provision unit 110 may be configured to provide the update model information 112 as a difference information in between the updated model information, e.g. being or comprising an updated model, and the reference information, e.g. being or comprising a base model.

Hence, having the base model available, a corresponding decoder 150, may modify parameters of the base model using the update model (e.g. parameters or parameter values thereof) to obtain an updated model, for example comprising or associated with NN parameters 102, without making a transmission of all NN parameters 102 necessary.

Furthermore, as an example, using encoding unit 120, encoder 100 may optionally be configured to provide the reference model information to a corresponding decoder 150, for example as a part of an encoded bitstream 106. Hence, decoder 150 may be provided with a reference, e.g. reference parameters of the base model within the reference model information 104 and a modification information, e.g. the update model information 112.

In addition, the update model provision unit 110 may be configured to determine a skip information 114 indicating whether a sequence of parameters of the update model is zero or not (alternatively, a skip information 114 may optionally be provided to the encoder 100 from an external source). Encoding unit 120 may hence be configured to provide and/or to encode the skip information 114 in an encoded bitstream for the corresponding decoder 150. The skip information may, for example, be a flag or an array of flags. Hence, update model information 112 may be compressed by representing NN parameters thereof, that may be zero or without significant impact, with a flag, such that these parameters do not have to be transmitted explicitly.

FIG. 1 further shows an apparatus 150 for decoding neural network parameters, which define a neural network. For brevity, apparatus 150 will be referred to as decoder 150. Decoder 150 comprises a decoding unit 160 and a modification unit 170.

As shown, decoder 150, or for example, decoding unit 160, may be configured to receive the encoded bitstream 106 comprising an update model information and a skip information (e.g. equal or equivalent to skip information 114). The decoding unit 160 may be configured to decode the bitstream 106 in order to provide an update model information 162 (e.g. equal or equivalent to update model information 112), comprising or being an update model which defines a modification of one or more layers of the neural network. Decoded update model information 162 may be provided to the modification unit 170.

Modification unit 170 is configured to modify parameters of a base model of the neural network using the update model information 162, in order to obtain an updated model information 108, e.g. comprising or being an updated model.

Therefore, as an optional feature, modification unit 170 may be provided with a reference model information, e.g. an information about a base model of the neural network, e.g. neural network parameters of the base model.

As an example, decoder 150, e.g. decoding unit 160, may be configured to obtain the reference model information 184 (e.g. equal or equivalent to reference model information 104), e.g. comprising or being parameters of the base model of the neural network which define one or more layers of the neural network, for example, from the encoded bitstream 106.

As an example, the reference model information 184 may, for example, be stored in an optional reference unit 180. Optionally, the reference unit 180 may comprise the reference model information 184, e.g. irrespective of a transmission thereof.

Hence, optionally, the decoding unit 160 and/or the reference unit 180 may provide the reference model information 184 to the modification unit 170. Accordingly, parameters of a base model included in the reference model information 104 may be adapted or modified or updated using the update model information 112 in order to provide the updated model information 108 comprising or being the updated model.

Furthermore, decoder 150, for example, decoding unit 160 may optionally be configured to decode the bitstream 106. Decoder 150 in order to provide a skip information 164 (e.g. equal or equivalent to skip information 114). As an example, decoding unit 160 or modification unit 170 may be configured to evaluate the skip information 164 indicating whether a sequence of parameters of the update model is zero or not.

As an example, after evaluating skip information 164, decoding unit 160 may adapt update model information 162 accordingly, e.g. such that parameters of the update model indicated to be zero by the skip information 114 are set to zero.

As another example, modification unit 170 may modify the base model according to the update model information 162 taking the skip information 164 in consideration, in order to obtain or provide updated model information 108.

As an optional feature, the update model information 112, 162 comprises or is an update model, wherein the update model describes differential values.

Hence, the differential values may, for example enable decoder 150, e.g. modification unit 170, to additively or subtractively combine the differential values with values of parameters of the base model, in order to obtain, e.g. corresponding, values of parameters of the updated model, e.g. of the updated model information 108.

Accordingly, decoder 100, e.g. modification unit 170, may be configured to additively or subtractively combine the differential values with values of parameters of the base model (e.g. from the reference model information 184), in order to obtain, e.g. corresponding, values of parameters of the updated model

Accordingly, as another optional feature, encoder 100, e.g. update model provision unit 110, may be configured to determine the differential values as a difference between values of parameters of the updated model, e.g. determined or represented by the NN parameters 102, and values of parameters of the base model, e.g. included in the reference model information 104.

As another optional feature, encoder 100, e.g. update model provision unit 110, may be configured to determine the differential values or differential tensors L_{Uk,j}, which are associated with a j-th layer of the neural network, such that a combination of the differential values or differential tensors L_{Uk,j}, with base value parameters or base value tensors L_{Bj} (e.g. included in the reference model information 104), which represent values of parameters of a j-th layer of a base model of the neural net, according to
L_{Nkj}=L_{Bi}+L_{Uk,j}, for all j, or for all j for which the update model comprises a layer
   allows for a determination of updated model value parameters or updated model value tensors L_{Nkj} (hence, for example, the updated model information 108), which represent values of parameters of a j-th layer of the updated model having model index k of the neural network.

Accordingly, decoder 150, e.g. modification unit 170, may be configured to combine differential values or differential tensors L_{Uk,j}, which are associated with a j-th layer of the neural network, with base value parameters or base value tensors Lg, which represent values of parameters of a j-th layer of a base model of the neural net, according to
L_{Nkj}=Lgi L_{Uk,j}, for all j, or for all j for which the update model comprises a layer
   in order to obtain updated model value parameters or updated model value tensors L_{Nkj}, which represent values of parameters of a j-th layer of an updated model (hence, for example, the updated model information 108) having model index k of the neural network.

Therefore, update model provision unit 110 and/or modification unit 170, may be configured to perform elementwise additions between tensors. However, it is to be noted that accordingly subtractions may as well be performed.

As another optional feature, the update model, e.g. 112, 162, may describe or comprise scaling factor values.

Hence, encoder 100, e.g. the update model provision unit 110, may be configured to provide the scaling factor values such that a scaling of values of parameters of the base model (e.g. included in the reference model information 104) using the scaling factor values, results in values of parameters of the updated model, e.g. 108.

Accordingly, decoder 150, e.g. modification unit 170, may be configured to scale values of parameters of the base model using the scaling factor values, in order to obtain values of parameters of the updated model, e.g. 108 or 102.

Accordingly, encoder 100, e.g. the update model provision unit 110, may be configured to determine the scaling factor values as a scaling factor between values of parameters of the updated model, e.g. 108 or 102, and values of parameters of the base model, e.g. based on the reference model information 104. As explained before, as an example, the updated model may be represented by the NN parameters 102. As another optional feature, the updated model, may be provided to the encoder 100.

As another optional feature, encoder 100, e.g. the update model provision unit 110, may be configured to determine the scaling values or scaling tensors L_{Uk,j}, which are associated with a j-th layer of the neural network, such that a combination of the scaling values or scaling tensors with base value parameters or base value tensors L_{Bj}, which represent values of parameters of a j-th layer of a base model of the neural net, according to
L_{Nk,j}=L_{Bj}·L_{Uk,j}, for all j, or for all j for which the update model comprises a layer
   allows for a determination of updated model value parameters or updated model value tensors L_{Nkj}, which represent parameters of a j-th layer of an updated model, e.g. 108, having model index k of the neural network.

Accordingly, decoder 150, e.g. modification unit 170, may be configured to combine scaling values or scaling tensors L_{Uk,j}, which are associated with a j-th layer of the neural network, with base value parameters or base value tensors L_{Bj}, which represent values of parameters of a j-th layer of a base model of the neural net, according to
L_{Nk,j}=L_{Bj}·L_{Uk,j}, for all j, or for all j for which the update model comprises a layer
   in order to obtain updated model value parameters or updated model value tensors L_{Nkj}, which represent values of parameters of a j-th layer of an updated model, e.g. 108, having model index k of the neural network.

Therefore, update model provision unit 110 and/or modification unit 170, may be configured to perform elementwise multiplications between tensors. However, it is to be noted that accordingly divisions may as well be performed.

As another optional feature, the update model, e.g. 112, 162 describes replacement values.

Therefore, encoder 100, e.g. the update model provision unit 110, may be configured to provide the replacement values such that a replacement of values of parameters of the base model, e.g. 184 using the replacement values, e.g. 162, allows to obtain values of parameters of the updated model, e.g. included in the updated model information 108.

Accordingly, decoder 150, e.g. modification unit 170, may be configured to replace values of parameters of the base model, e.g. included in reference information 184, using the replacement values, e.g. included in 162, in order to obtain values of parameters of the updated model, e.g. included in 108.

Accordingly, encoder 100, e.g. the update model provision unit 110, may be configured to determine the replacement values.

As another optional example, the neural network parameters, e.g. 102, comprise weight values defining weights of neuron interconnections which emerge from a neuron or which lead towards a neuron.

As another optional feature, a sequence of neural network parameters comprises weight values which are associated with a row or column of a matrix. The inventors, recognized that a row-wise or column-wise processing may be performed efficiently. As an example, encoder 1010, e.g. update model provision unit 110 and/or decoder 150, e.g. modification unit 170 may be configured to process matrices efficiently, or may be optimized for processing matrices.

As another optional feature, the skip information 114 and/or 164 comprises a flag indicating whether all parameters of a sequence of parameters of the update model, e.g. 112, 162, are zero or not. Hence, instead of a zero sequence, only the skip information 114 may be encoded in the bitstream 106 using encoding unit 120, requiring less transmission resources. On the decoder side, a modification of base model parameters associated with update values, e.g. weights, being zero may be skipped based on an evaluation of the skip information 164. Accordingly, decoder 150, e.g. modification unit 170, may be configured to selectively skip a decoding of a sequence of parameters of the update model in dependence on the skip information 164.

Accordingly, as another optional feature, encoder 100, e.g. the update model provision unit 110, may be configured to provide the skip information 114 to signal a skipping of a decoding of a sequence of parameters of the update model, e.g. 112.

As another optional feature, encoder 100, e.g. the update model provision unit 110, may be configured to provide a skip information 114 comprising an information whether a sequence of parameters of the update model, e.g. 112, have a predetermined value.

Accordingly, decoder 150, e.g. modification unit 170, may be configured to selectively set values of a sequence of parameters of the update model, e.g. 162, to a predetermined value in dependence on the skip information.

Hence, a differentiated information may be provided by the skip information. Neural network parameters may be flagged being zero or non-zero, and in the case of being non-zero, even a predetermined value may be indicated. Or it may be indicated that a set or sequence of parameters can be represented by a predetermined value, e.g. as an approximation of neural network parameters.

As another optional feature, the skip information, 114 and/or 164, comprises an array of skip flags, indicating whether all parameters of respective sequences of parameters of the update model, e.g. 108, are zero or not. The inventors recognized that an indication for a plurality of sequences, e.g. for rows and columns of neural network parameter matrices, may be summarized in an array of skip flags. Such an array may be encoded, transmitted and decoded efficiently.

As another optional feature, encoder 100, e.g. update model provision unit 110, may be configured to provide skip flags, e.g. included in skip flag information 114, associated with respective sequences of parameters to signal a skipping of a decoding of a respective sequences of parameters of the update model, e.g. 112. Flags may be represented by few bits, for a simple indication of a skipping of parameters.

Accordingly, decoder 150, e.g. decoding unit 160, may be configured to selectively skip a decoding of a respective sequences of parameters of the update model, e.g. from the encoded bitstream 106, in dependence on respective skip flags, e.g. included in skip information 164, associated with respective sequences of parameters.

As another example, encoder 100, e.g. the update model provision unit 110, may be configured to provide an array size information describing a number of entries of the array of skip flags. Optionally, the update model information 114 may comprise the array size information.

Accordingly, decoder 150, e.g. modification unit 170, may be configured to evaluate an array size information, e.g. included in the update model information 162, describing a number of entries of the array of skip flags.

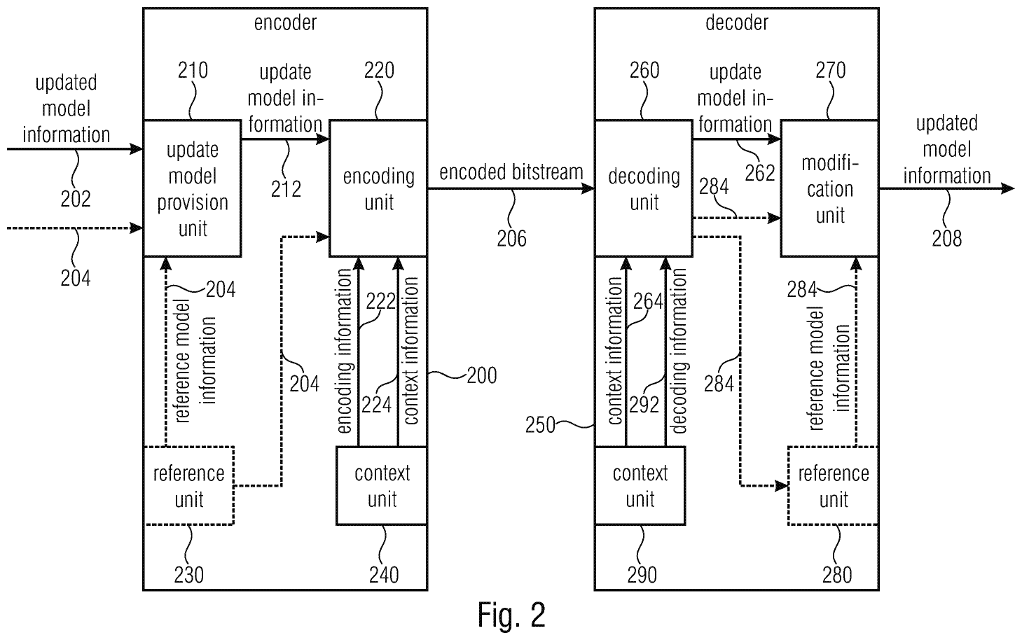

As another optional example, encoder 100, e.g. encoding unit 120, may be configured to encode one or more skip flags, e.g. included in skip information 114, using a context model, and to select a context model for an encoding of one or more skip flags in dependence on one or more previously encoded symbols, e.g. symbols of the update model information 112 and/or of the skip information 114. Hence, encoding unit 120 may comprise one or more context models, or may be provided with one context model to choose whether to use the context model or with more context models to choose from. As an optional feature, encoder 100 and/or decoder 150 may comprise a context unit, which may comprise context models to choose from, that may be provided to a respective coding unit (encoding/decoding), e.g. as further explained in the context of FIG. 2.

Accordingly, decoder 150, e.g. decoding unit 160, may be configured to decode one or more skip flags using a context model and to select a context model for a decoding of one or more skip flags in dependence on one or more previously decoded symbols. Accordingly, decoding unit 160 may comprise one or more context models, or may be provided with one or more context models, e.g. via encoded bitstream 106. Hence, optionally, encoder 100, e.g. encoding unit 120 may be configured to encode and/or to transmit one or more context models.

As another optional feature, encoder 100, e.g. the encoding unit 120, may be configured to apply a single context model for an encoding of all skip flags associated with a layer of the neural network. Accordingly, decoder 150, e.g. decoding unit 160, may be configured to apply a single context model for a decoding of all skip flags associated with a layer of the neural network. Hence, encoding and/or decoding may be performed with low computational costs.

As another optional feature, encoder 100, e.g. the encoding unit 120, may be configured to select a context model for an encoding of a skip flag in dependence on a previously encoded skip flag. Accordingly decoder 150, e.g. decoding unit 160, may be configured to select a context model for a decoding of a skip flag in dependence on a previously decoded skip flag. Hence, an inventive encoder and an inventive decoder may be configured to exploit or take advantage of a correlation between subsequent skip flags. This may allow to increase coding efficiency. The correlation of information may be used in the form of the context model.

Furthermore, in general and as another optional feature, encoding unit 120 may be configured to store an information about previously encoded information and decoding unit 160 may be configured to store an information about previously decoded information.

As another optional feature, encoder 100, e.g. the encoding unit 120, may be configured to select a context model for an encoding of a skip flag, e.g. included in skip information 114, in dependence on a value of a corresponding skip flag in a previously encoded neural network model. Accordingly, decoder 150, e.g. decoding unit 160, may be configured to select a set of context models selectable for a decoding of a skip flag in dependence on a value of a corresponding skip flag in a previously decoded neural network model. The inventors recognized that for increasing coding efficiency, a correlation not only between subsequent skip flags of a single model but as well corresponding skip flags of different models (e.g. between a current model and a previously encoded/decoded update or a previously encoded/decoded base model) may be used or exploited. This correlation may be mapped to respective context models and used by selection of an appropriate context model.

As another optional feature, encoder 100, e.g. the encoding unit 120, may be configured to select a set of context models selectable for an encoding of a skip flag in dependence on a value of a corresponding skip flag in a previously encoded neural network model. Accordingly, decoder 150, e.g. decoding unit 160, may be configured to select a set of context models selectable for a decoding of a skip flag in dependence on a value of a corresponding skip flag in a previously decoded neural network model. As a further degree of freedom, a set of context models may be chosen, e.g. before choosing a respective context model out of the set of context models. Hence, a method may be provided to select a good or even best matching context in order to provide a good coding efficiency. As explained before, encoding unit 120 and/or decoding unit 160 may be configured to store an information about preceding encoded/decoded information, for a following context selection.

As another optional feature, encoder 100, e.g. the encoding unit 120, may be configured to select a set of context models selectable for an encoding of a skip flag in dependence on an existence of a corresponding layer in a previously encoded neural network model. Accordingly, decoder 150, e.g. decoding unit 160, may be configured to select a set of context models selectable for a decoding of a skip flag in dependence on an existence of a corresponding layer in a previously decoded neural network model. Hence, an inventive approach may cope with topology changes of neural networks, e.g. in between training steps. Hence, coding may be performed efficiently, even with flexible network topologies.

As another optional feature, encoder 100, e.g. encoding unit 120, may be configured to select a context model out of the selected set of context models in dependence on one or more previously encoded symbols of a currently encoded update model. Accordingly, decoder 150, e.g. decoding unit 160, may be configured to select a context model out of the selected set of context models in dependence on one or more previously decoded symbols of a currently decoded update model.

FIG. 2 shows a schematic view of a second apparatus for encoding neural network parameters and of a second apparatus for decoding neural network parameters, according to embodiments of the invention.

FIG. 2 shows apparatus 200 for encoding neural network parameters, which define a neural network. For brevity, apparatus 200 will be referred to as encoder 200.

Encoder 200 comprises an update model provision unit 210, and an encoding unit 220. As an optional example, encoder 200, e.g. update model provision unit 210 may be configured to receive an updated model information 202, for example, being or comprising an updated model.

Alternatively, e.g. as explained in context of FIG. 1, update model provision unit may, for example, be configured to receive NN parameters associated with, or of, an updated model.

Based thereon, the update model provision unit 210 may be configured to provide an update model information, e.g. being or comprising a current, e.g. recent, update model, such that the update model enables a decoder to modify parameters of a base model of the neural network, or intermediate parameters derived from the base model of the neural network using one or more intermediate update models, using the current update model, in order to obtain an updated model.

Therefore, as another optional feature, encoder 200 may optionally comprise a reference unit 230, for example, configured to provide a reference model information, for example, comprising a reference model, parameters of which are to be modified using update model information 212, for example, comprising an information about the base model or intermediate parameters derived from the base model or for example, about intermediate updated models (e.g. partially updated models based on the base model).

As another optional feature, encoder 100 may be configured to receive an update model information, e.g. being or comprising a current update model, e.g. instead of the updated model information 202. In this case, encoder 200 may not comprise update model provision unit 210. Encoding unit 220 may encode the update model information, which may define a modification of one or more layers of the neural network, or a modification of one or more intermediate layers or of the neural network. Hence, encoder 200 may provide an update model information such that the update model enables a decoder, e.g. 250, to modify parameters of a base model of the neural network, or intermediate parameters derived from the base model of the neural network using one or more intermediate update models, using the current update model, in order to obtain an updated model, e.g. 208.

As an example, optional reference unit 230 may comprise such a reference model information 204, or may for example, be provided, e.g. once with such a reference model information (not shown). As another example, update model provision unit 210 may optionally be configured to receive a reference model information 204.

For example, based on the reference model information, the update model provision unit 210 may be configured to provide or even to determine an update model, e.g. as a model indicating a difference between a base model and an updated model.

The update model information 212, e.g. being or comprising such an update model, may then be provided to the encoding unit 220. Encoding unit 220 is configured to entropy-encode one or more parameters of the current update model. Hence, update model information 212, or portions thereof, e.g. parameters, parameter values, flags, symbols thereof, may be encoded in a bitstream 206.

Furthermore, encoding unit 220 is configured to adapt a context used for an entropy-encoding of one or more parameters of the current update model in dependence on one or more previously encoded parameters of the base model and/or in dependence on one or more previously encoded parameters of an intermediate update model.

As shown in FIG. 2, encoder 200 may comprise a context unit 240, comprising an information about one or more context models for encoding update model information 212. For example, based on an optional encoding information 222, comprising or being one or more previously encoded parameters and/or one or more previously encoded parameters of an intermediate update model, context unit 240 may provide a context information 224, for example comprising or being a context or a context model, to the encoding unit 220.

Accordingly, encoding unit 220 may optionally store an information about such previously encoded parameters.

As explained before, encoder 200 may optionally be configured to obtain a reference model information, e.g. being or comprising parameters of a base mode of the neural network which define one or more layers of the neural network. Hence, this information 204 may optionally, be provided to encoding unit 220, in order to be provided, e.g. to a corresponding decoder. Hence, reference model information 204 may be encoded in bitstream 206.

As another optional example, encoding unit 220 may optionally be configured to encode context information 240 in the encoded bitstream 206.

Furthermore, FIG. 2 shows an apparatus 250 for decoding neural network parameters, which define a neural network. For brevity, apparatus 250 will be referred to as decoder 250. Decoder 250 comprises a decoding unit 260 and a modification unit 270.

As optionally shown, decoder 200, e.g. decoding unit 260 may receive encoded bitstream 206. The bitstream may comprise or may be an encoded version of the update model information 212.

Decoding unit 260 is configured to decode a current update model (for example, by decoding the update model information encoded in the bitstream 206) which defines a modification of one or more layers of the neural network, or a modification of one or more intermediate layers or of the neural network. Hence, decoding unit 260 may provide an update model information 262, being or comprising the current update model. Update model information 262 may, for example, be equal or equivalent to update model information 212.

The decoding unit 260 is configured to entropy-decode one or more parameters of the current update model. Accordingly, update model information 262 may comprise these decoded parameters. Update model information 262 may, for example, be equal or equivalent to update model information 212.

Furthermore, decoding unit 260 is configured to adapt a context used for an entropy-decoding of one or more parameters of the current update model in dependence on one or more previously decoded parameters of the base model and/or in dependence on one or more previously decoded parameters of an intermediate update model.

Therefore, decoder 250 comprises context unit 290. For example, based on an optional decoding information, for example, being or comprising one or more previously decoded parameters of the base model and/or one or more previously decoded parameters of an intermediate update model, the context unit 290 may provide a context information 264, for example being or comprising the context or a corresponding context model. Optionally, context information 264 may be equal or equivalent to context information 224.

Hence, decoding unit 260 may optionally be configured to store an information about such previously decoded parameters.

Furthermore, update model information 262 is provided to modification unit 270. Modification unit 270 is configured to modify parameters of a base model of the neural network, or intermediate parameters derived from the base model of the neural network using one or more intermediate update models, using the current update model, in order to obtain an updated model 208. As shown modification unit 270 may be configured to provide an updated model information 208 comprising or being the updated model. Furthermore updated model information 208 may, for example be equal or equivalent to updated model information 202.

As explained before, the update model information 262 may be or may comprise the current update model. As optionally shown, modification unit 270 may, for example, be provided with a reference model information 284. Reference model information 284 may be or may comprise the base model or an intermediate model, or for example, parameters of the base model of the neural network, or intermediate parameters (or respective values thereof).

Furthermore, reference model information 284 may, for example, be equal to or equivalent to reference model information 204.

As an optional feature, decoder 250 may, for example, comprise a reference unit, configure to provide the reference model information 284 to the modification unit 270.

As another optional feature, decoding unit 260 may receive the reference model information 284, e.g. via bitstream 206, and may provide information 284 to the modification unit 270. In this case, reference unit 280 may, for example, not be present.

As another example, decoding unit 260 may receive the reference model information 284, e.g. via bitstream 206 and may provide the reference model information 284, e.g. once, to the reference unit 280, to be stored there.

Hence, decoder 250 may optionally be configured to obtain, e.g. decode, parameters of a base model of the neural network which define one or more layers of the neural network.

As an optional feature, encoder 200, e.g. encoding unit 220, may, for example, be configured to encode quantized and binarized representations of one or more parameters of the current update model, e.g. 212 in other words, for example included in update model information 212, using a context-based entropy encoding, e.g. using a context information 224.

The inventors recognized that the context-based entropy encoding may allow to provide a good trade-off between computational effort and coding efficiency.

Accordingly, decoder 250, e.g. decoding unit 260, may, for example, be configured to decode quantized and binarized representations of one or more parameters of the current update model, e.g. encoded in bitstream 206, using a context-based entropy decoding, e.g. using a context information 264.

As an optional feature, encoder 200, e.g. encoding unit 220, may, for example, be configured to entropy-encode at least one significance bin associated with a currently considered parameter value of the current update model, e.g. 212, the significance bin describing whether a quantization index of the currently considered parameter value is equal to zero or not. Update model information 212 may, for example, comprise the at least one significance bin. The significance bin may, for example, be encoded in bitstream 206.

Accordingly, decoder 250, e.g. decoding unit 260, may, for example, be configured to entropy-decode at least one significance bin associated with a currently considered parameter value of the current update model, the significance bin describing whether a quantization index of the currently considered parameter value is equal to zero or not.

Optionally, update model information 262 may, for example, comprise the at least one decoded significance bin.

As an optional feature, encoder 200, e.g. encoding unit 220, may, for example, be configured to entropy-encode at least one sign bin associated with a currently considered parameter value of the current update model, e.g. 212, the sign bin describing whether a quantization index of the currently considered parameter value is greater than zero or smaller than zero. Update model information 212 may, for example, comprise the at least one sign bin. The sign bin may, for example, be encoded in bitstream 206.

Accordingly, decoder 250, e.g. decoding unit 260, may, for example, be configured to entropy-decode at least one sign bin associated with a currently considered parameter value of the current update model, the sign bin describing whether a quantization index of the currently considered parameter value is greater than zero or smaller than zero. Optionally, update model information 262 may, for example, comprise the at least one decoded sign bin.

As an optional feature, encoder 200, e.g. encoding unit 220, may, for example, be configured to entropy-encode a unary sequence associated with a currently considered parameter value of the current update model, e.g. 212, the bins of the unary sequence describing whether an absolute value of a quantization index of the currently considered parameter value is greater a respective bin weight or not. Update model information 212 may, for example, comprise the unary sequence. The unary sequence may be encoded in bitstream 206.

Accordingly, decoder 250, e.g. decoding unit 260, may, for example, be configured to entropy-decode an unary sequence associated with a currently considered parameter value of the current update model, the bins of the unary sequence describing whether an absolute value of a quantization index of the currently considered parameter value is greater a respective bin weight or not. Optionally, update model information 262 may, for example, comprise the decoded unary sequence.

As an optional feature, encoder 200, e.g. encoding unit 220, may, for example, be configured to entropy-encode one or more greater-than-X bins indicative of an absolute value of a quantization index of the currently considered parameter value being greater than X or not, wherein X is an integer greater than zero. Update model information 212 may, for example, comprise the one or more greater-than-X bins. The one or more greater-than-X bins may, for example, be encoded in bitstream 206.

Accordingly, decoder 250, e.g. decoding unit 260, may, for example, be configured to entropy-decode one or more greater-than-X bins indicative of an absolute value of a quantization index of the currently considered parameter value being greater than X or not, wherein X is an integer greater than zero. Optionally, update model information 262 may, for example, comprise the one or more decoded greater-than-X bins.

As an optional feature, encoder 200, e.g. encoding unit 220 and/or context unit 240 may, for example, be configured to select a context model, e.g. 224, for an encoding of one or more bins of a quantization index of the currently considered parameter value in dependence on a value of a previously encoded corresponding parameter value in a previously encoded neural network model.

Therefore, encoding unit 220 may optionally be configured to store or comprise an information about values of previously encoded corresponding parameter values in a previously encoded neural network model. Optional encoding information 222 may, for example, comprise the value of the previously encoded corresponding parameter value. The update model information 212 may, for example, comprise the one or more bins of the quantization index of the currently considered parameter value.

Accordingly, decoder 250, e.g. decoding unit 260 and/or context unit 290, may, for example, be configured to select a context model, e.g. 264, for a decoding of one or more bins of a quantization index of the currently considered parameter value in dependence on a value of a previously decoded corresponding parameter value in a previously decoded neural network model.

Therefore, decoding unit 260 may optionally be configured to store or comprise an information about values of previously decoded corresponding parameter values in a previously decoded neural network model. Optional decoding information 292 may, for example, comprise the value of the previously decoded corresponding parameter value in the previously decoded neural network model, e.g. for a selection of the context in context unit 290.

As an optional feature, encoder 200, e.g. encoding unit 220 and/or context unit 240 may, for example, be configured to select a set of context models, e.g. 224, selectable for an encoding of one or more bins of a quantization index of the currently considered parameter value in dependence on a value of a previously encoded corresponding parameter value in a previously encoded neural network model.

Therefore, encoding unit 220 may optionally be configured to store or comprise an information about values of previously encoded corresponding parameter values in a previously encoded neural network model.

Optional encoding information 222 may, for example, comprise the value of the previously encoded corresponding parameter value in the previously encoded neural network model. The context information 224 may optionally comprise the set of context models selected. The update model information 212 may, for example, comprise the one or more bins of the quantization index of the currently considered parameter value.

Accordingly, decoder 250, e.g. decoding unit 260 and/or context unit 290, may, for example, be configured to select a set of context models, e.g. 224, selectable for a decoding of one or more bins of a quantization index of the currently considered parameter value in dependence on a value of a previously decoded corresponding parameter value in a previously decoded neural network model.

Therefore, decoding unit 260 may optionally be configured to store or comprise an information about values of previously decoded corresponding parameter values in a previously decoded neural network model.

The context information 264 may comprise the set of context models selected. The update model information 212 may, for example, comprise the one or more decoded bins of a quantization index of the currently considered parameter value. Optional decoding information 292 may, for example, comprise the value of the previously decoded corresponding parameter value in the previously decoded neural network model.

As an optional feature, encoder 200, e.g. encoding unit 220 and/or context unit 240 may, for example, be configured to select a context model, e.g. 224, for an encoding of one or more bins of a quantization index of the currently considered parameter value in dependence on an absolute value of a previously encoded corresponding parameter value in a previously encoded neural network model.

Alternatively, encoder 200, e.g. encoding unit 220 and/or context unit 240 may, for example, be configured to select a set of context models, e.g. 264, for an encoding of one or more bins of a quantization index of the currently considered parameter value in dependence on an absolute value of a previously encoded corresponding parameter value in a previously encoded neural network model.

Context information 224 may, for example, comprise the selected context model or the selected set of context models. Encoding information 222 may, for example, comprise the absolute value of the previously encoded corresponding parameter value in the previously encoded neural network model. Therefore, encoding unit 220 may optionally be configured to store or comprise an information about absolute values of previously encoded corresponding parameter values in a previously encoded neural network model. The update model information 212 may, for example, comprise the one or more bins of the quantization index of the currently considered parameter value.

Accordingly, decoder 250, e.g. decoding unit 260 and/or context unit 290, may, for example, be configured to select a context model, e.g. 264, for a decoding of one or more bins of a quantization index of the currently considered parameter value in dependence on an absolute value of a previously decoded corresponding parameter value in a previously decoded neural network model.

Alternatively, decoder 250, e.g. decoding unit 260 and/or context unit 290, may, for example, be configured to select a set of context models for a decoding of one or more bins of a quantization index of the currently considered parameter value in dependence on an absolute value of a previously decoded corresponding parameter value in a previously decoded neural network model.

Context information 264 may, for example, comprise the selected context model or set of context models. Decoding information 222 may, for example, comprise the absolute value of the previously decoded corresponding parameter value in the previously decoded neural network model. Therefore, decoding unit 260 may optionally be configured to store or comprise an information about absolute values of previously decoded corresponding parameter values in a previously decoded neural network model. The update model information 262 may, for example, comprise the one or more decoded bins of the quantization index of the currently considered parameter value.

As an optional feature, encoder 200, e.g. update model provision unit 210, may, for example, be configured compare a previously encoded corresponding parameter value in a previously encoded neural network model with one or more threshold values.

Optionally, encoder 200 may be configured to select a context model, e.g. 224, for an encoding of one or more bins of a quantization index of the currently considered parameter value in dependence on a result of the comparison.

Alternatively, encoder 200 may, for example, be configured to select a set of context models, e.g. 224, for an encoding of one or more bins of a quantization index of the currently considered parameter value in dependence on a result of the comparison.

As an example, a first set may, for example, be chosen if the corresponding or co-located parameter is lower than a first threshold T1, e.g. such that a second set is chosen if the corresponding or co-located parameter is greater than or equal to the first threshold T1, and e.g. such that a third set is chosen if the corresponding or co-located parameter is greater than or equal to a threshold T2.

Context information 224 may, for example, comprise the selected context model or set of context models. The update model information 212 may, for example, comprise the one or more bins of a quantization index of the currently considered parameter value. Accordingly, encoding unit 220 may, for example, be configured to store or comprise an information about previously encoded corresponding parameter values and/or about the one or more threshold values. Furthermore, the encoding information 222 may, for example, comprise the result of the comparison.

Accordingly, decoder 250, e.g. decoding unit 260 and/or context unit 290, may, for example, be configured to compare a previously decoded corresponding parameter value in a previously decoded neural network model with one or more threshold values.

Optionally, decoder 250 may, for example, be configured to select a context model, e.g. 224, for a decoding of one or more bins of a quantization index of the currently considered parameter value in dependence on a result of the comparison.

Alternatively, decoder 250 may, for example, be configured to select a set of context models for a decoding of one or more bins of a quantization index of the currently considered parameter value in dependence on a result of the comparison.

Context information 264 may, for example, comprise the selected context model or set of context models. The update model information 212 may, for example, comprise the decoded one or more bins of a quantization index of the currently considered parameter value. Furthermore, the decoding information 292 may, for example, comprise the result of the comparison. Accordingly, decoding unit 260 may, for example, be configured to store or comprise an information about previously decoded corresponding parameter values and/or about the one or more threshold values.

As an optional feature, encoder 200, e.g. encoding unit 220 may, for example, be configured compare a previously encoded corresponding parameter value in a previously encoded neural network model with a single threshold value.

Optionally, encoder 200, e.g. encoding unit 220 and/or context unit 240, may, for example, be configured to select a context model, e.g. 224, for an encoding of one or more bins of a quantization index of the currently considered parameter value in dependence on a result of the comparison with the single threshold value.

Alternatively, encoder 200, e.g. encoding unit 220 and/or context unit 240, may, for example, be configured to select a set of context models, e.g. 224, for an encoding of one or more bins of a quantization index of the currently considered parameter value in dependence on a result of the comparison with the single threshold value.

Therefore, encoding unit 220 may optionally be configured to store or comprise an information about previously encoded corresponding parameter values and/or may comprise the threshold value.

Context information 264 may, for example, comprise the selected context model or set of context models. The update model information 212 may optionally comprise the one or more bins of the quantization index of the currently considered parameter value. The encoding information 222 may optionally comprise the result of the comparison with the single threshold value.

Accordingly, decoder 250, e.g. decoding unit 260, may, for example, be configured compare a previously decoded corresponding parameter value in a previously decoded neural network model with a single threshold value.

Optionally, decoder 250, e.g. decoding unit 260 and/or context unit 290, may, for example, be configured to select a context model, e.g. 264, for a decoding of one or more bins of a quantization index of the currently considered parameter value in dependence on a result of the comparison with the single threshold value

Alternatively, decoder 250, e.g. decoding unit 260 and/or context unit 290, may, for example, be configured to select a set of context models, e.g. 264, for a decoding of one or more bins of a quantization index of the currently considered parameter value in dependence on a result of the comparison with the single threshold value.

Therefore, decoding unit 260 may optionally be configured to store or comprise an information about previously decoded corresponding parameter values and/or about the threshold value.

Context information 264 may, for example, comprise the selected context model or set of context models. The update model information 262 may optionally comprise the decoded one or more bins of the quantization index of the currently considered parameter value. The decoding information 292 may optionally comprise the result of the comparison with the single threshold value.

As an optional feature, encoder 200, e.g. encoding unit 220, may, for example, be configured compare an absolute value of a previously encoded corresponding parameter value in a previously encoded neural network model with one or more threshold values.

Optionally, encoder 200, e.g. encoding unit 220 and/or context unit 240 may, for example, be configured to select a context model, e.g. 224, for an encoding of one or more bins of a quantization index of the currently considered parameter value in dependence on a result of the comparison.

Alternatively, encoder 200, e.g. encoding unit 220 and/or context unit 240 may, for example, be configured to select a set of context models, e.g. 224, for an encoding of one or more bins of a quantization index of the currently considered parameter value in dependence on a result of the comparison

Therefore, encoding unit 220 may optionally be configured to store absolute values of previously encoded corresponding parameter values and may comprise the one or more threshold values.

Context information 224 may, for example, comprise the selected context model or set of context models. The update model information 212 may optionally comprise the one or more bins of the quantization index of the currently considered parameter value. The encoding information 222 may optionally comprise the result of the comparison with the one or more threshold values.

Accordingly, decoder 250, e.g. decoding unit 260, may, for example, be configured compare an absolute value of a previously decoded corresponding parameter value in a previously decoded neural network model with one or more threshold values.

Optionally, decoder 250, e.g. decoding unit 260 and/or context unit 290, may, for example, be configured to select a context model, e.g. 224, for a decoding of one or more bins of a quantization index of the currently considered parameter value in dependence on a result of the comparison.

Alternatively, decoder 250, e.g. decoding unit 260 and/or context unit 290, may, for example, be configured to select a set of context models, e.g. 224, for a decoding of one or more bins of a quantization index of the currently considered parameter value in dependence on a result of the comparison

Therefore, decoding unit 260 may optionally be configured to store or comprise an information about absolute values of previously decoded corresponding parameter values and/or about the one or more threshold values.

Context information 264 may, for example, comprise the selected context model or set of context models. The update model information 262 may optionally comprise the decoded one or more bins of the quantization index of the currently considered parameter value. The decoding information 292 may optionally comprise the result of the comparison with the one or more threshold values, e.g. for the selection of the context information.

As an optional feature, encoder 200, e.g. encoding unit 220, may, for example, be configured to entropy-encode at least one significance bin associated with a currently considered parameter value of the current update model, e.g. 212, the significance bin describing whether a quantization index of the currently considered parameter value is equal to zero or not, and to select a context, e.g. 224, for the entropy-encoding of the at least one significance bin, or a set of contexts, e.g. 224 for the entropy-encoding of the at least one significance bin, in dependence on a value of a previously encoded corresponding parameter value in a previously encoded neural network model

Context information 224 may, for example, comprise the selected context model or set of context models. Therefore, encoding unit 220 may optionally be configured to store an information about values of previously encoded corresponding parameter values. The update model information 212 may optionally comprise the at least one significance bin. The encoding information 222 may optionally comprise the value of the previously encoded corresponding parameter value for context selection, e.g. using context unit 240.

Accordingly, decoder 250, e.g. decoding unit 260, may, for example, be configured to entropy-decode at least one significance bin associated with a currently considered parameter value of the current update model, the significance bin describing whether a quantization index of the currently considered parameter value is equal to zero or not and to select a context, e.g. 264, for the entropy-decoding of the at least one significance bin, or a set of contexts, e.g. 264, for the entropy-decoding of the at least one significance bin, in dependence on a value of a previously decoded corresponding parameter value in a previously decoded neural network model

Context information 264 may, for example, comprise the selected context model or set of context models. Therefore, decoding unit 260 may optionally be configured to store an information about values of previously decoded corresponding parameter values.

The update model information 262 may optionally comprise the at least one decoded significance bin. The decoding information 292 may optionally comprise the value of the previously decoded corresponding parameter value for the context selection, e.g. using context unit 290.

As an optional feature, encoder 200, e.g. encoding unit 220, may, for example, be configured to entropy-encode at least one sign bin associated with a currently considered parameter value of the current update model, the sign bin describing whether a quantization index of the currently considered parameter value is greater than zero or smaller than zero, and to select a context, e.g. 224, for the entropy-encoding of the at least one sign bin, or a set of contexts, e.g. 224, for the entropy-encoding of the at least one sign bin, in dependence on a value of a previously encoded corresponding parameter value in a previously encoded neural network model.

Context information 224 may, for example, comprise the selected context model or set of context models. Therefore, encoding unit 220 may optionally be configured to store an information about values of previously encoded corresponding parameter values.

The update model information 212 may optionally comprise the at least one sign bin. The encoding information 222 may optionally comprise the value of the previously encoded corresponding parameter value for context selection, e.g. using context unit 240.

Accordingly, decoder 250, e.g. decoding unit 260, may, for example, be configured to entropy-decode at least one sign bin associated with a currently considered parameter value of the current update model, the sign bin describing whether a quantization index of the currently considered parameter value is greater than zero or smaller than zero, and to select a context, e.g. 224, for the entropy-decoding of the at least one sign bin, or a set of contexts, e.g. 224, for the entropy-decoding of the at least one sign bin, in dependence on a value of a previously decoded corresponding parameter value in a previously decoded neural network model.

Context information 264 may, for example, comprise the selected context model or set of context models. Therefore, decoding unit 260 may optionally be configured to store an information about values of previously decoded corresponding parameter values.

The update model information 262 may optionally comprise the at least one decoded sign bin. The decoding information 292 may optionally comprise the value of the previously decoded corresponding parameter value for the context selection, e.g. using context unit 290.

As an optional feature, encoder 200, e.g. encoding unit 220, may, for example, be configured to entropy-encode one or more greater-than-X bins indicative of an absolute value of a quantization index of the currently considered parameter value being greater than X or not, wherein X is an integer greater than zero, and to select a context, e.g. 224, for the entropy-encoding of the at least one greater-than-X bin, or a set of a contexts, e.g. 224, for the entropy-encoding of the at least one greater-than-X bin, in dependence on a value of a previously encoded corresponding parameter value in a previously encoded neural network model.

Context information 224 may, for example, comprise the selected context model or set of context models. Therefore, encoding unit 220 may optionally be configured to store an information about values of previously encoded corresponding parameter values.

The update model information 212 may optionally comprise the one or more greater-than-X bins. The encoding information 222 may optionally comprise the value of the previously encoded corresponding parameter value for context selection, e.g. using context unit 240.

Accordingly, decoder 250, e.g. decoding unit 260, may, for example, be configured to entropy-decode one or more greater-than-X bins indicative of an absolute value of a quantization index of the currently considered parameter value being greater than X or not, wherein X is an integer greater than zero, and to select a context, e.g. 264, for the entropy-decoding of the at least one greater-than-X bin, or a set of a contexts, e.g. 264, for the entropy-decoding of the at least one greater-than-X bin, in dependence on a value of a previously decoded corresponding parameter value in a previously decoded neural network model.

Context information 264 may, for example, comprise the selected context model or set of context models. Therefore, decoding unit 260 may optionally be configured to store an information about values of previously decoded corresponding parameter values in previously decoded neural network models.

The update model information 262 may optionally comprise the one or more greater-than-X bins. The decoding information 292 may optionally comprise the value of the previously decoded corresponding parameter value for the context selection, e.g. using context unit 290.

As another optional feature, encoder 200, e.g. encoding unit 220 and/or context unit 240 may, for example, be configured to choose a context model out of a selected set of context models in dependence on one or more previously encoded bins or parameters of the current update model.

Hence, context information 224 may comprise the selected set of context models, and encoding unit 220 may choose one context model out of the set of context models. Alternatively, context information 224 may be or may comprise the chosen context model. As an example the one or more previously encoded bins or parameters of the current update model may be provided to the context unit 240 for context selection using encoding information 222.

Accordingly, decoder 250, e.g. decoding unit 260 and/or context unit 290, may, for example, be configured to choose a context model out of a selected set of context models in dependence on one or more previously decoded bins or parameters of the current update model.

Hence, in general, it is to be noted that encoding unit 220 may, for example, be configured to store an information about previously encoded information, e.g. e.g. symbols, models, values, absolute values and/or bins.

Accordingly, in general, it is to be noted that decoding unit 260 may, for example, be configured to store an information about previously decoded information, e.g. symbols, models, values, absolute values and/or bins.

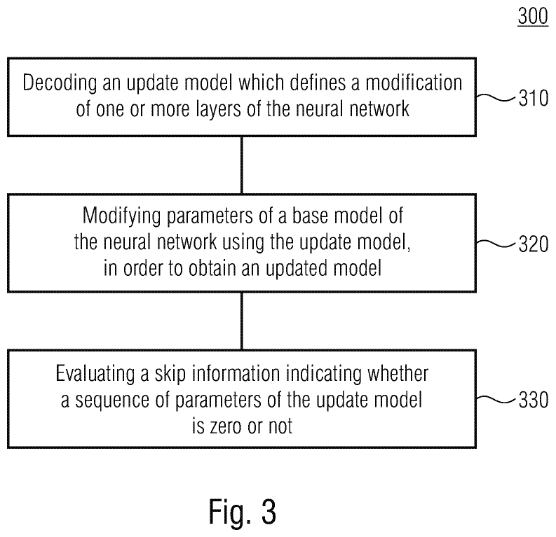

FIG. 3 shows a method for decoding neural network parameters, which define a neural network, according to embodiments of the invention. The method 300 comprises decoding 310 an update model which defines a modification of one or more layers of the neural network, and modifying 320 parameters of a base model of the neural network using the update model, in order to obtain an updated model, and evaluating 330 a skip information indicating whether a sequence of parameters of the update model is zero or not.

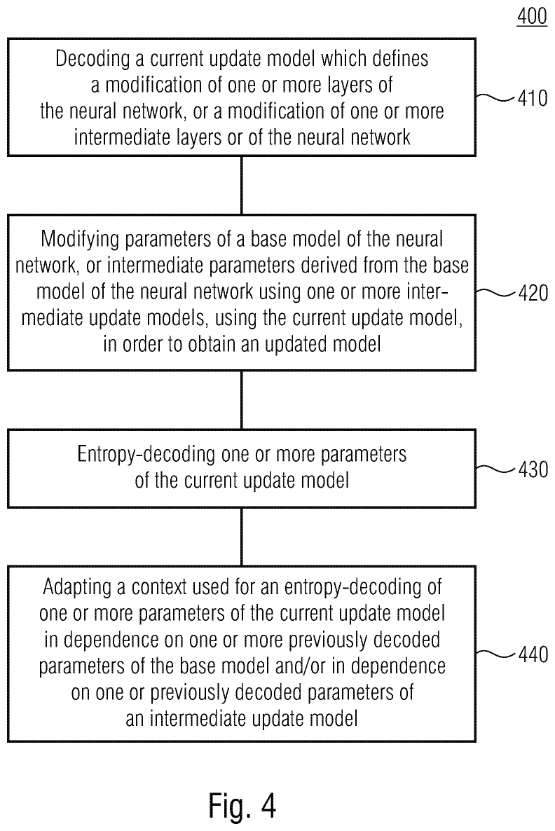

FIG. 4 shows a method for decoding neural network parameters, which define a neural network, according to embodiments of the invention. The method 400 comprises decoding 410 a current update model which defines a modification of one or more layers of the neural network, or a modification of one or more intermediate layers or of the neural network, and modifying 420 parameters of a base model of the neural network, or intermediate parameters derived from the base model of the neural network using one or more intermediate update models, using the current update model, in order to obtain an updated model, and entropy-decoding 430 one or more parameters of the current update model and adapting 440 a context used for an entropy-decoding of one or more parameters of the current update model in dependence on one or more previously decoded parameters of the base model and/or in dependence on one or previously decoded parameters of an intermediate update model.

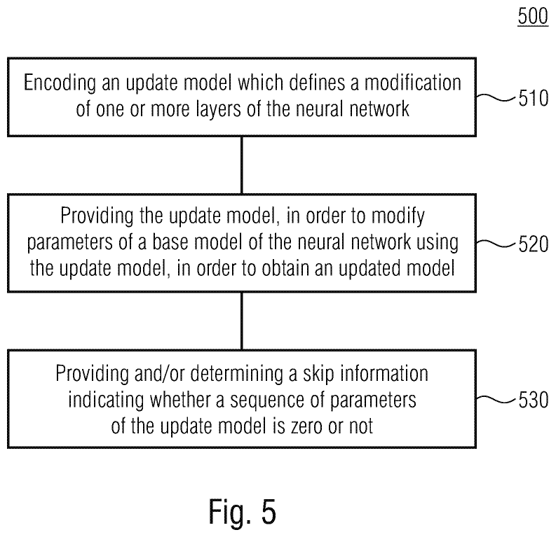

FIG. 5 shows a method for encoding neural network parameters, which define a neural network, according to embodiments of the invention. The method 500 comprises encoding 510 an update model which defines a modification of one or more layers of the neural network, and providing 520 the update model, in order to modify parameters of a base model of the neural network using the update model, in order to obtain an updated model, and providing 530 and/or determining a skip information indicating whether a sequence of parameters of the update model is zero or not.

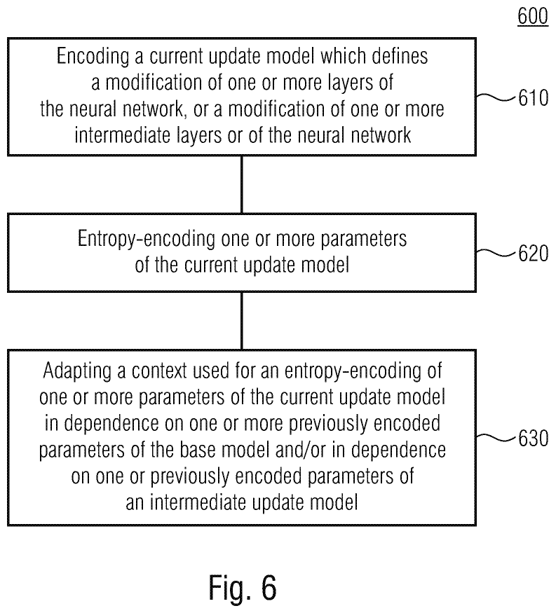

FIG. 6 shows a method for encoding neural network parameters, which define a neural network, according to embodiments of the invention. The method 600 comprises encoding 610 a current update model which defines a modification of one or more layers of the neural network, or a modification of one or more intermediate layers or of the neural network, in order to modify parameters of a base model of the neural network, or intermediate parameters derived from the base model of the neural network using one or more intermediate update models, using the current update model, in order to obtain an updated model, and entropy-encoding 620 one or more parameters of the current update model, and adapting 630 a context used for an entropy-encoding of one or more parameters of the current update model in dependence on one or more previously encoded parameters of the base model and/or in dependence on one or previously encoded parameters of an intermediate update model.

Further embodiments according to the invention comprise a temporal context adaption. Embodiments may comprise an adaption of context models or context information, for example, over time.

Furthermore, it is to be noted that embodiments can be applied to the compression of entire neural networks, and some of them can also be applied to the compression of differential updates of neural networks with respect to a base network. Such differential updates are for example useful when models are redistributed after fine-tuning or transfer learning, or when providing versions of a neural network with different compression ratios.

Embodiments may further address usage, e.g. manipulation or modification of base neural network, e.g. neural network serving as reference for a differential update.

Embodiments may further address or comprise or provide updated neural network, e.g. neural network resulting from modifying the base neural network. Note: The updated neural network may, for example, be reconstructed by applying a differential update to the base neural network.

Further embodiments according to the invention may comprise syntax elements in the form of NNR units. A NNR unit may, for example be a data structure for carrying neural network data and/or related metadata which may be compressed or represented, e.g. according to embodiments of the invention.

NNR units may carry at least one of a compressed information about neural network metadata, uncompressed information about neural network metadata, topology information, complete or partial layer data, filters, kernels, biases, quantized weights, tensors and alike.

An NNR unit may, for example comprise, or consist of the following data elements
NNR unit size (optional): This data element may signal the total byte size of the NNR Unit, including the NNR unit size.
NNR unit header: This data element may comprise or contain information about the NNR unit type and/or related metadata.
NNR unit payload: This data element may comprise or contain compressed or uncompressed data related to the neural network.

As an example, embodiments may comprise (or use) the following bitstream syntax (wherein, for example, numBytesInNNRUnit may designate a size of a nnr_unit bitstream element):

| | |
|---|---|
| nnr_unit( numBytesInNNRUnit ) { | Descriptor |
| nnr_unit_size( ) (optional) | |
| nnr_unit_header( ) | |
| nnr_unit_payload( ) | |
| } | |

| | |
|---|---|
| nnr_unit_header( ) { | Descriptor |
| nnr_unit_type | u(6) |
| nnr_compressed_data_unit_payload_type | u(5) |
| ... | |
| further optional configuration information | |
| ... | |
| if ( nnr_unit_type == NNR_NDU ) | |
| nnr_compressed_data_unit_header( ) | |
| ... | |
| further optional configuration information | |
| ... | |
| } | |

| | |
|---|---|
| nnr_compressed_data_unit_header( ) { | Descriptor |
| nnr_compressed_data_unit_payload_type | u(5) |
| ... | |
| Further optional configuration information | |
| ... | |
| node_id_present_flag | u(1) |
| if( node_id_present_flag ) { | |
| device_id | ue(1) |
| parameter_id | ue(5) |
| put_node_depth | ue(4) |
| } | |
| parent_node_id_present_flag | u(1) |
| if( parent_node_id_present_flag ) { | |
| parent_node_id_type | u(2) |
| temporal_context_modeling_flag | u(1) |
| if( parent_node_id_type == ICNN_NDU_ID ) { | |
| parent_device_id | ue(1) |
| if( !node_id_present_flag ) { | |
| parameter_id | ue(5) |
| put_node_depth | ue(4) |
| } | |
| } else if( parent_node_id_type == | |
| ICNN_NDU_PL_SHA256 ) | |
| parent_node_payload_sha256 | u(256) |
| else | |
| parent_node_payload_sha512 | u(512) |
| } | |
| ... | |
| further optional configuration information | |
| ... | |
| } | |

The parent node identifier, may for example comprise one or more of the above syntax elements, to name some, e.g. device_id, parameter_id and/or put_node_depth.

| | |
|---|---|
| nnr_unit_payload( ) { | Descriptor |
| ... | |
| further optional configuration information | |
| ... | |
| if( nnr_unit_type == NNR_NDU ) | |
| nnr_compressed_data_unit_payload( ) | |
| ... | |
| further optional configuration information | |

...
}

| | |
|---|---|
| nnr_compressed_data_unit_payload( ) { | Descriptor |
| if( nnr_compressed_data_unit_payload_type == NNR_PT | |
| _RAW_FLOAT ) | |
| for( i = 0; i < Prod( TensorDimensions ); i++ ) | |
| raw_float32_parameter[ TensorIndex( TensorDimension | flt(32) |
| s, i , 0 ) ] | |
| decode_compressed_data_unit_payload( ) | |
| } | |

Using the decode_compressed_data_unit_payload( ) parameters of a base model of the neural network may be modified in order to obtain an updated model.

node_id_present_flag equal to 1 may indicate that syntax elements device_id, parameter_id, and/or put_node_depth are present.

device_id may, for example, uniquely identify the device that generated the current NDU.

parameter_id may, for example, uniquely identify the parameter of the model to which the tensors stored in the NDU relate to. If parent_node_id_type is equal to ICNN_NDU_ID, parameter_id may, for example, or shall equal the parameter_id of the associated parent NDU.

put_node_depth may, for example, be the tree depth at which the current NDU is located. A depth of 0 may correspond to the root node. If parent_node_id_type is equal to ICNN_NDU_ID, put_node_depth−1 may, for example, be or even has to be equal the put_node_depth of the associated parent NDU.

parent_node_id_present_flag equal to 1 may, for example, indicate that syntax element parent_node_id_type is present.

parent_node_id_type may, for example, specify the parent node id type. It may indicate which further syntax elements for uniquely identifying the parent node are present. Examples for the allowed values for parent_node_id_type are defined in Table 2.

TABLE 2
Parent node id type identifiers (example).

| parent_node_id_type | Identifier | Description |
|---|---|---|
| 0 | ICNN_NDU_ID | Indicates that syntax elements |
| | | parent_device_id, parameter_id, |
| | | and put_node_depth are present |
| 1 | ICNN_NDU_PL_SHA256 | Indicates that syntax element |
| | | parent_node_payload_sha256 is |
| | | present |
| 2 | ICNN_NDU_PL SHA512 | Indicates that syntax element |
| | | parent_node_payload_sha512 is |
| | | present |
| 3 | | Reserved |

temporal_context_modeling_flag may, for example, specify whether temporal context modeling is enabled. A temporal_context_modeling_flag equal to 1 may indicate that temporal context modeling is enabled. If temporal_context_modeling_flag is not present, it is inferred to be 0.

parent_device_id may, for example, be equal to syntax element device_id of the parent NDU.

parent_node_payload_sha256 may, for example, be a SHA256 hash of the nnr_compressed_data_unit_payload of the parent NDU.

parent_node_payload_sha512 may, for example, be a SHA512 hash of the nnr_compressed_data_unit_payload of the parent NDU.

Furthermore, embodiments according to the invention may comprise a row skipping feature. As an example, if enabled by flag row_skip_flag_enabled_flag, the row skipping technique signals one flag row_skip_list[i] for each value i along the first axis of the parameter tensor. If the flag row_skip_list[i] is 1, all elements of the parameter tensor for which the index for the first axis equals i are set to zero. If the flag row_skip_list[i] is 0, all elements of the parameter tensor for which the index for the first axis equals i are encoded individually.

Furthermore, embodiments according to the invention may comprise a context modelling. As an example, context modelling may correspond to associating the three type of flags sig_flag, sign_flag, and abs_level_greater_x/x2 with context models. In this way, flags with similar statistical behavior may be or should be associated with the same context model so that the probability estimator (inside of the context model) can, for example, adapt to the underlying statistics.

The context modelling of the presented approach may, for example, be as follows:

For example, twenty-four context models may be distinguished for the sig_flag, depending on the state value and whether the neighbouring quantized parameter level to the left is zero, smaller, or larger than zero.

If dq_flag is 0, only the first three context models may, for example, be used.

Three other context models may, for example, be distinguished for the sign_flag depending on whether the neighbouring quantized parameter level to the left is zero, smaller, or larger than zero.

For the abs_level_greater_x/x2 flags, each x may, for example, be use either one or two separate context models. If x<=maxNumNoRemMinus1, two context models are distinguished depending on the sign_flag. If x>maxNumNoRemMinus1, only one context model may, for example, be used.

Furthermore, embodiments according to the invention may comprise temporal context modelling. As an example, if enabled by flag temporal_context_modeling_flag, additional context model sets for flags sig_flag, sign_flag and abs_level_greater_x may be available. The derivation of ctxIdx may then be also based on the value of a quantized co-located parameter level in the previously encoded parameter update tensor, which can, for example, be uniquely identified by the parameter update tree. If the co-located parameter level is not available or equal to zero, the context modeling e.g. as explained before may be applied. Otherwise, if the co-located parameter level is not equal to zero, the temporal context modeling of the presented approach may be as follows:

Sixteen context models may, for example, be distinguished for the sig_flag, depending on the state value and whether the absolute value of the quantized co-located parameter level is greater than one or not.

If dq_flag is 0, only the first two additional context models may be used.

Two more context models may, for example, be distinguished for the sign_flag depending on whether the quantized co-located parameter level is smaller or greater than zero.

For the abs_level_greater_x flags, each x may use two separate context models. These two context models may, for example, be distinguished depending on whether the absolute value of the quantized co-located parameter level is greater or equal to x-1 or not.

Embodiments according to the invention may optionally comprise the following tensor syntax, e.g. a quantized tensor syntax.

| | |
|---|---|
| quant_tensor( dimensions, maxNumNoRemMinus1, | Descriptor |
| entryPointOffset ) { | |
| tensor2DHeight = dimensions[ 0 ] | |
| tensor2DWidth = Prod( dimensions ) / tensor2DHeight | |
| if( general_profile_idc == 1 && tensor2DWidth > 1 ) { | |
| row_skip_enabled_flag | uae(1) |
| if( row_skip_enabled_flag ) | |
| for( i = 0; i < tensor2DHeight; i++ ) | |
| row_skip_list[ i ] (optional) | ae(v) |
| } | |
| stateId = 0 (optional) | |
| bitPointer = get_bit_pointer( ) (optional) | |
| lastOffset = 0 (optional) | |
| for( i = 0; i < Prod( dimensions ); i++ ) { | |
| idx = TensorIndex( dimensions, i, scan_order ) | |
| (optional) | |
| if( entryPointOffset != - 1 && | |
| GetEntryPointldx( dimensions, i, scan_order ) != | |
| -1 && | |
| scan_order > 0 ) { (optional) | |
| lvlCurrRange = 256 (optional) | |
| j = entryPointOffset + | |
| GetEntryPointldx( dimensions, i, scan_order ) | |
| (optional) | |
| lvlOffset = cabac_offset_list[ j ] (optional) | |
| if( dq_flag ) (optional) | |
| stateId = dq_state_list[ j ] (optional) | |
| set_bit_pointer( bitPointer + lastOffset + | |
| BitOffsetList[ j ] ) (optional) | |
| lastOffset = BitOffsetList[ j ] (optional) | |
| init_prob_est_param( ) (optional) | |
| } | |
| QuantParam[ idx ] = 0 | |
| if( general_profile_idc != 1 \| tensor2DWidth <= 1 \|\| | |
| !row_skip_enabled_flag \|\| | |
| !row_skip_list[ idx[ 0 ] ] ) | |
| int_param( idx, maxNumNoRemMinus1, stateId ) | e.g. as explained in the |
| (optional) | following |
| ... | |
| further optional configuration information | |
| ... | |
| } | |
| } | |

The skip information may, for example, comprise any or all of the above row skip information e.g. row_skip_enabled_flag and/or row_skip_list.

As an example, row_skip_enabled_flag may specify whether row skipping is enabled. A row_skip_enabled_flag equal to 1 may indicate that row skipping is enabled.

row_skip_list may specify a list of flags where the i-th flag row_skip_Isit[i] may indicate whether all tensor elements of QuantParam for which the index for the first dimension equals i are zero. If row_skip_list[i] is equal to 1, all tensor elements of QuantParam for which the index for the first dimension equals i may be zero.

Embodiments according to the invention may, for example, further comprise a quantized parameter syntax, as an example a syntax as defined in the following (All elements may be considered as optional)

| | |
|---|---|
| int_param( i, maxNumNoRemMinus1, stateId ) { | Descriptor |
| [symbol] | |
| sig_flag | ae(v) |
| if( sig_flag ) { | |
| QuantParam[ i ]++ | |
| sign_flag | ae(v) |
| j = −1 | |
| do { | |
| j++ | |
| abs_level_greater_x[ j ] | ae(v) |
| QuantParam[ i ] += abs_level_greater_x[ j ] | |
| } while( abs_level_greater_x[ j ] == 1 && j < | |
| maxNumNoRemMinus1 ) | |
| if( abs_level_greater_x[ j ] == 1 ) { | |
| RemBits = 0 | |
| j = −1 | |
| do { | |
| j++ | |
| abs_level_greater_x2[ j ] | ae(v) |
| if( abs_level_greater_x2[ j ] ) { | |
| QuantParam[i] += 1 << RemBits | |
| RemBits++ | |
| } | |
| } while( abs_level_greater_x2[ j ] && j < 30) | |
| abs_remainder | uae(RemBits) |
| QuantParam[ i ] += abs_remainder | |
| } | |
| QuantParam[ i ] = sign_flag ? -QuantParam[ i ] : | |
| QuantParam[ i] | |
| } | |
| } | |

sig_flag may, for example, specify whether the quantized weight QuantParam[i] is nonzero. A sig_flag equal to 0 may, for example, indicate that QuantParam[i] is zero. sign_flag may, for example, specify whether the quantized weight QuantParam[i] is positive or negative. A sign_flag equal to 1 may, for example, indicate that QuantParam[i] is negative. abs_level_greater_x[j] may, for example, indicate whether the absolute level of QuantParam[i] is greater j+1.

abs_level_greater_x2[j] may, for example, comprise the unary part of the exponential Golomb remainder.

abs_remainder may, for example, indicate a fixed length remainder.

Further embodiments according to the invention may, for example, comprise the following shift parameter indices syntax (All elements may be considered as optional).

| | |
|---|---|
| shift_parameter_ids( maxNumNoRemMinus1 ) { | Descriptor |
| for( i = 0; i < (dq_flag ? 24 : 3; i++ ) { | |
| shift_idx( i, ShiftParameterIdsSigFlag ) | |
| } | |
| if(temporal_context_modeling_flag){ | |
| for( i = 24; i < (dq_flag ? 40 : 26); i++ ) { | |
| shift_idx( i, ShiftParameterIdsSignFlag ) | |
| } | |
| } | |
| for( i = 0; i < ( temporal_context_modeling_flag ? 5:3 ); | |
| i++ ) { | |
| shift_idx( i, ShiftParameterIdsSignFlag ) | |
| } | |
| for( i = 0; i < (temporal_context_modeling_flag ? 4 : | |
| 2)*(maxNumNoRemMinus1+1); i++ ) { | |
| shift_idx( i, ShiftParameterIdsAbsGrX ) | |
| } | |
| for( i = 0; i < 31; i++ ) { | |
| shift_idx( i, ShiftParameterIdsAbsGrX2 ) | |
| } | |
| } | |

Further embodiments according to the invention comprise entropy decoding processes, as explained in the following.

In general inputs to this process may, for example, be a request for a value of a syntax element and values of prior parsed syntax elements.

Output of this process may, for example be the value of the syntax element.

The parsing of syntax elements may, for example, proceed as follows:

For each requested value of a syntax element a binarization may, for example, bederived.

The binarization for the syntax element and the sequence of parsed bins may, for example, determine the decoding process flow.

Example for Initialization process according to embodiments:

In general, outputs of this process may, for example, be initialized DeepCABAC internal variables.

The context variables of the arithmetic decoding engine may, for example, be initialized as follows:

The decoding engine may, for example, register IvICurrRange and IvIOffset both in 16 bit register precision may, for example, be initialized by invoking the initialization process for the arithmetic decoding engine.

Embodiments according to the invention may comprise an initialization process for probability estimation parameters, e.g. as explained in the following.

Outputs of this process may, for example, be the initialized probability estimation parameters shift0, shift1, pStateIdx0, and pStateIdx1 for each context model of syntax elements sig_flag, sign_flag, abs_level_greater_x, and abs_level_greater_x2.

The 2D array CtxParameterList [ ][ ] may, for example, beinitialized as follows:

CtxParameterList[ ][ ]={{1, 4, 0, 0}, {1, 4, −41, −654}, {1, 4, 95, 1519}, {0, 5, 0, 0}, {2, 6, 30, 482}, {2, 6, 95, 1519}, {2, 6, −21, −337}, {3, 5, 0, 0}, {3, 5, 30, 482}}

If dq_flag is equal to 1 and temporal_context_modeling_flag is equal to 1, for each of the e.g. 40 context models of syntax element sig_flag, the associated context parameter shift( ) may, for example, beset to CtxParameterList[setId][0], shift1 may, for example, be set to CtxParameterList[setId][1], pStateIdx0 may, for example, be set to CtxParameterList[setId][2], and pStateIdx1 may, for example, be set to CtxParameterList[setId][3], where i may, for example, be the index of the context model and where setId may, for example, be equal to ShiftParameterIdsSigFlag[i].

If dq_flag==is equal to 1 and temporal_context_modeling_flag is equal to 0, e.g. for each of the first e.g. 24 context models of syntax element sig_flag, the associated context parameter shift0 may, for example, be set to CtxParameterList[setId][0], shift1 may, for example, be set to CtxParameterList[setId][1], pStateIdx0 may, for example, be set to CtxParameterList[setId][2], and pStateIdx1 may, for example, be set to CtxParameterList[setId][3], where i may, for example, be the index of the context model and where setId may, for example, be equal to ShiftParameterIdsSigFlag[i].

If dq_flag is equal to 0 and temporal_context_modeling_flag is equal to 1, e.g. for each of the e.g. first 3 context models and e.g. context models 24 to 25 of syntax element sig_flag, the associated context parameter shift0 may, for example, be set to CtxParameterList[setId][0], shift1 may, for example, be set to CtxParameterList[setId][1], pStateIdx0 may, for example, be set to CtxParameterList[setId][2], and pStateIdx1 may, for example, be set to CtxParameterList[setId][3], where i may, for example, be the index of the context model and where setId may, for example, be equal to ShiftParameterIdsSigFlag [i].

If temporal_context_modeling_flag is equal to 1, e.g. for each of the for example 5 context models of syntax element sign_flag, the associated context parameter shift0 may, for example, be set to CtxParameterList[setId][0], shift1 may, for example, be set to CtxParameterList[setId][1], pStateIdx0 may, for example, be set to CtxParameterList[setId][2], and pStateIdx1 may, for example, be set to CtxParameterList[setId][3], where i may, for example, be the index of the context model and where setId may, for example, be equal to ShiftParameterIdsSignFlag[i].

Otherwise, (temporal_context_modeling_flag==0), e.g. for each of the first e.g. 3 context models of syntax element sign_flag, the associated context parameter shift0 may, for example, be set to CtxParameterList[setId][0], shift1 may, for example, be set to CtxParameterList[setId][1], pStateIdx0 may, for example, be set to CtxParameterList[setId][2], and pStateIdx1 may, for example, be set to CtxParameterList[setId][3], where i may, for example, be the index of the context model and where setId may, for example, be equal to ShiftParameterIdsSignFlag[i].

If temporal_context_modeling_flag is equal to 1, e.g. for each of the 4*(cabac_unary_length_minus1+1) context models of syntax element abs_level_greater_x, the associated context parameter shift0 may, for example, be set to CtxParameterList[setId][0], shift1 may, for example, be set to CtxParameterList[setId][1], pStateIdx0 may, for example, be set to CtxParameterList[setId][2], and pStateIdx1 may, for example, be set to CtxParameterList[setId][3], where i may, for example, be the index of the context model and where setId may, for example, be equal to ShiftParameterIdsAbsGrX[i].

Otherwise, (temporal_context_modeling_flag==0), e.g. for each of the first e.g. 2*(cabac_unary_length_minus1+1) context models of syntax element abs_level_greater_x, the associated context parameter shift0 may, for example, be set to CtxParameterList[setId][0], shift1 may, for example, be set to CtxParameterList[setId][1], pStateIdx0 may, for example, be set to CtxParameterList[setId][2], and pStateIdx1 may, for example, be set to CtxParameterList[setId][3], where i may, for example, be the index of the context model and where setId may, for example, be equal to ShiftParameterIdsAbsGrX[i].

Further embodiments according to the invention may comprise a decoding process flow, e.g. as explained in the following.

In general, inputs to this process may, for example, be all bin strings of the binarization of the requested syntax element.

Output of this process may, for example, be the value of the syntax element.

This process may specify how e.g. each bin of a bin string is parsed e.g. for each syntax element. After parsing e.g. each bin, the resulting bin string may, for example, be compared to e.g. all bin strings of the binarization of the syntax element and the following may apply:
If the bin string is equal to one of the bin strings, the corresponding value of the syntax element may, for example, be the output.
Otherwise (the bin string is not equal to one of the bin strings), the next bit may, for example, be parsed.

While parsing each bin, the variable binIdx may, for example, be incremented by 1 starting with binIdx being set equal to 0 for the first bin.

The parsing of each bin may, for example, be specified by the following two ordered steps:
1. A derivation process for ctxIdx and bypassFlag as may, for example, be invoked e.g. with binIdx as input and ctxIdx and bypassFlag as outputs.
2. An arithmetic decoding process may, for example, be invoked with ctxIdx and bypassFlag as inputs and the value of the bin as output.

Further embodiments according to the invention may comprise a derivation process of ctxInc for the syntax element sig_flag.

Inputs to this process may, for example, be the sig_flag decoded before the current sig_flag, the state value stateId, the associated sign_flag, if present, and, if present, the co-located parameter level (coLocParam) from the incremental update decoded before the current incremental update. If no sig_flag was decoded before the current sig_flag, it may, for example, be inferred to be 0. If no sign_flag associated with the previously decoded sig_flag was decoded, it may, for example, be inferred to be 0. If no co-located parameter level from an incremental update decoded before the current incremental update is available, it is inferred to be 0. A co-located parameter level means the parameter level in the same tensor at the same position in previously decoded incremental update.

Output of this process is the variable ctxInc.

The variable ctxInc is derived as follows:
If coLocParam is equal to 0 the following applies:
If sig_flag is equal to 0, ctxInc is set to stateId*3.
Otherwise, if sign_flag is equal to 0, ctxInc is set to stateId*3+1.
Otherwise, ctxInc is set to stateId*3+2.
If coLocParam is not equal to 0 the following applies:
If coLocParam is greater than 1 or less than −1, ctxInc is set to stateId*2+24.
Otherwise, ctxInc is set to stateId*2+25.

Further embodiments according to the invention may comprise a derivation process of ctxInc for the syntax element sign_flag.

Inputs to this process may, for example, be the sig_flag decoded before the current sig_flag, the associated sign_flag, if present, and, if present, the co-located parameter level (coLocParam) from the incremental update decoded before the current incremental update. If no sig_flag was decoded before the current sig_flag, it may, for example, be inferred to be 0. If no sign_flag associated with the previously decoded sig_flag was decoded, it may, for example, be inferred to be 0. If no co-located parameter level from an incremental update decoded before the current incremental update is available, it may, for example, be inferred to be 0. A co-located parameter level means the parameter level in the same tensor at the same position in previously decoded incremental update.

Output of this process may, for example, be the variable ctxInc.

The variable ctxInc may, for example, be derived as follows:
If coLocParam is equal to 0 the following may apply:
If sig_flag is equal to 0, ctxInc may, for example, be set to 0.
Otherwise, if sign_flag is equal to 0, ctxInc may, for example, be set to 1.
Otherwise, ctxInc may, for example, be set to 2.
If coLocParam is not equal to 0 the following may apply:
If coLocParam is less than 0, ctxInc may, for example, be set to 3.
Otherwise, ctxInc may, for example, be set to 4.

Further embodiments may comprise a derivation process of ctxInc for the syntax element abs_level_greater_x[j]

Inputs to this process may, for example, be the sign_flag decoded before the current syntax element abs_level_greater_x[j] and, if present, the co-located parameter level (coLocParam) from the incremental update decoded before the current incremental update. If no co-located parameter level from an incremental update decoded before the current incremental update is available, it may, for example, be inferred to be 0. A co-located parameter level means the parameter level in the same tensor at the same position in previously decoded incremental update.

Output of this process may, for example, be the variable ctxInc.

The variable ctxInc may, for example, be derived as follows:
If coLocParam is equal to zero the following may apply:
If sign_flag is equal to 0, ctxInc may, for example, be set to 2*j.
Otherwise, ctxInc may, for example, be set to 2*j+1.
If coLocParam is not equal to zero the following may apply:
If coLocParam is greater or equal to j or is lower or equal to −j, ctxInc may, for example, be set to 2*j+2*maxNumNoRemMinus1
Otherwise, ctxInc may, for example, be set to 21+2*macNumNoRemMinus1+1.

Further remarks:

In the following, different inventive embodiments and aspects will be described in a chapter “Application area”, in a chapter “Aspects of embodiments according to the invention”, and in a chapter “Aspects of the invention”.

Also, further embodiments will be defined by the enclosed claims.

It should be noted that any embodiments as defined by the claims can be supplemented by any of the details (features and functionalities) described in the above mentioned chapters and/or subchapters respectively and/or by any of the details (features and functionalities) described in the above disclosure.

Also, the embodiments described in the above mentioned chapters and/or subchapters respectively can be used individually, and can also be supplemented by any of the features in another chapter and/or subchapter respectively, or by any feature included in the claims.

Also, it should be noted that individual aspects described herein can be used individually or in combination. Thus, details can be added to each of said individual aspects without adding details to another one of said aspects.

It should also be noted that the present disclosure describes, explicitly or implicitly, features usable in a neural network parameter encoder or in a neural network parameter update encoder (apparatus for providing an encoded representation of neural network parameters or updates thereof) and in a neural network parameter decoder or in a neural network parameter update decoder (apparatus for providing a decoded representation of neural network parameters or neural network parameter updates on the basis of an encoded representation). Thus, any of the features described herein can be used in the context of a neural network encoder and in the context of a neural network decoder.

Moreover, features and functionalities disclosed herein relating to a method can also be used in an apparatus (configured to perform such functionality). Furthermore, any features and functionalities disclosed herein with respect to an apparatus can also be used in a corresponding method. In other words, the methods disclosed herein can be supplemented by any of the features and functionalities described with respect to the apparatuses.

Also, any of the features and functionalities described herein can be implemented in hardware or in software, or using a combination of hardware and software, as will be described in the section “implementation alternatives”.

The following section may be titled method for entropy coding of parameters of incremental updates of neural networks, e.g. comprising subsections or chapters 1 to 3.

In the following, aspects of embodiments of the invention are disclosed. The following may provide a general idea of aspects of embodiments of the invention. It should be noted that any embodiments as defined by the claims can optionally be supplemented by any of the details (features and functionalities) described in the following. Also, the embodiments and aspects thereof described in the following can be used individually, and can also, optionally, be supplemented by any of the features in another chapter and/or subchapter respectively, or by any feature included in the claims and/or by any of the details (features and functionalities) described in the above disclosure. Embodiments may comprise said aspects and/or features alone or in combination.

Embodiments and/or aspects of the invention may describe a method for parameter coding of incremental updates of a set of neural network parameters (e.g. also referred to as weights, weight parameter or parameters), for example, using entropy encoding methods. For example, similarly to encoding of (e.g. full) neural network parameters, this may comprise quantization, lossless encoding and/or lossless decoding methods. For example, usually, incremental updates may not be sufficient to reconstruct a neural network model but may e.g. provide differential updates to an existing model. For example, due to the fact, that their architecture, e.g. the architecture of the updates, may be similar or for example even identical to related full neural network models, for example many or even all existing methods for neural network compression (as for example given in MPEG-7 part 17 standard for compression of neural networks for multimedia content description and analysis [2]) may be applicable.

The basic structure of having a base model and one or more incremental updates may, for example, enables new methods, e.g. in context modeling for entropy coding, which are described in this disclosure. In other words, embodiments according to the invention may comprise base models and one or more incremental updates, using context modeling methods for entropy coding.

Embodiments and/or aspects of the invention may, for example, be mainly targeted on a lossy coding of layers of neural network parameters in neural network compression, but it can also be applied to other areas of lossy coding. In other words, embodiments according to the invention may comprise, for example additionally, methods for lossy coding.

The methodology of, for example an apparatus according to embodiments of the invention, or the apparatus may be divided into different main parts, which may comprise or may consist of at least one of the following:
1. Quantization
2. Lossless Encoding
3. Lossless Decoding

In order to understand the main advantages of embodiments of the invention, in the following a brief introduction on the topic of neural networks and on related methods for parameter coding will be disclosed. It is to be noted, that any aspects and/or features disclosed in the following may be incorporated in embodiments according to the invention and/or embodiments of the invention may be supplemented by said features and aspects.

### 1 Application Area

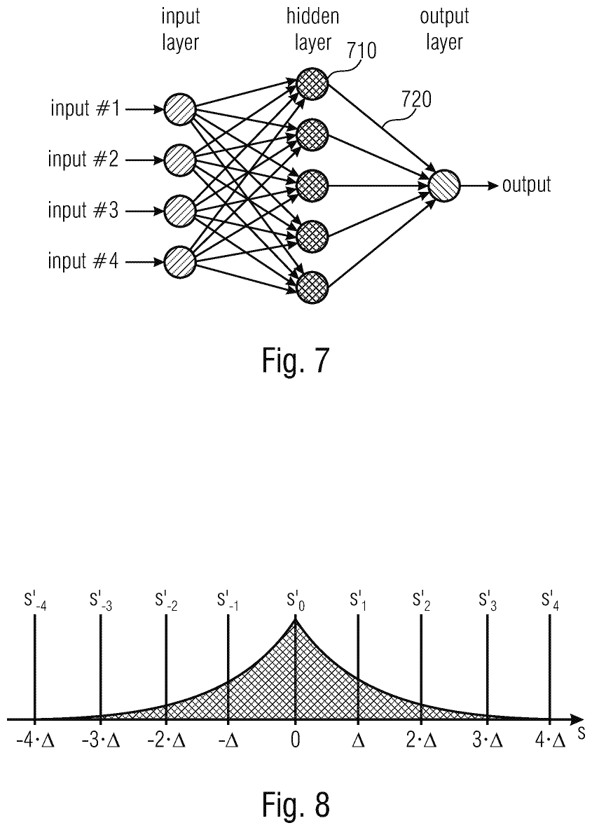

In their most basic form, neural networks may, for example, constitute a chain of affine transformations, for example, followed by an element-wise non-linear function. They may be represented as a directed acyclic graph, for example, as depicted in FIG. 7. FIG. 7 shows an example of a graph representation of a feed forward neural network, e.g. a feed forward neural network. Specifically, this 2-layered neural network is a non linear function which maps a 4-dimensional input vector into the real line. Each node 710 may entail a particular value, which may be forward propagated into the next node, for example, by multiplication with the respective weight value of the edge 720. All incoming values may, for example, then simply be aggregated.

Mathematically, the above neural network may calculate or would calculate the output, for example, in the following manner:

output=σ(W₂·σ(W₁·input))

where W2 and W1 may be the neural networks weight parameters (edge weights) and sigma may be some non-linear function. For instance, so-called convolutional layers may also be used, for example, by casting them as matrix-matrix products, for example, as described in [1]. Incremental updates may, for example, usually aim at providing updates for the weights of W1 and/or W2 and can be, for example, the outcome of an additional training process. The updated versions of W2 and W1 may, for example, usually lead to a modified output. From now on, we will refer as inference the procedure of calculating the output from a given input. Also, we will call intermediate results as hidden layers or hidden activation values, which may, for example, constitute a linear transformation+element-wise non-linearity, e.g., such as the calculation of the first dot product+non-linearity above.

For example, usually, neural networks may be equipped with millions of parameters, and may thus require hundreds of MB in order to be represented. Consequently, they may require high computational resources in order to be executed since their inference procedure may, for example, involve computations of many dot product operations, for example, between large matrices. Hence, it may be of high importance to reduce the complexity of performing these dot products.

### 2 Aspects of Embodiments According to the Invention

2.1 Related Methods for Quantization and Entropy Coding

MPEG-7 part 17 standard for compression of neural networks for multimedia content description and analysis [2] provides different methods for quantization of the neural network parameters, as for example independent scalar quantization and dependent scalar quantization (DQ or also trellis-coded quantization TCQ). Additionally, it specifies an entropy quantization scheme also known as deepCABAC [7]. These methods are briefly summarized for a better understanding. Details can be found in [2]. It is to be noted that embodiments according to the invention (e.g. as described in section 3 and as defined by the claims) may comprise any features and/or aspects of said methods or standard, especially the features and/or aspects explained in the following, alone or in combination.

2.1.1 Scalar Quantizers (Optional; Details are all Optional)

The neural network parameters can, for example, be quantized using scalar quantizers. As a result of the quantization, the set of admissible values for the parameters may, for example, be reduced. In other words, the neural network parameters may be mapped to a countable set (for example, in practice, a finite set) of so-called reconstruction levels. The set of reconstruction levels may represent a proper subset of the set of possible neural network parameter values. For simplifying the following entropy coding, the admissible reconstruction levels may, for example, be represented by quantization indexes, which may be transmitted as part of the bitstream. At the decoder side, the quantization indexes may, for example, be mapped to reconstructed neural network parameters. The possible values for the reconstructed neural network parameters may correspond to the set of reconstruction levels. At the encoder side, the result of scalar quantization may be a set of (integer) quantization indexes.

According to embodiments, for example, in this application uniform reconstruction quantizers (URQs) may be used. Their basic design is illustrated in FIG. 8. FIG. 8 shows an example of an illustration of uniform reconstruction quantizer, according to embodiments of the invention. URQs may have the property that the reconstruction levels are equally spaced. The distance Δ between two neighboring reconstruction levels is referred to as quantization step size. One of the reconstruction levels may, for example, be equal to 0. Hence, the complete set of available reconstruction levels may, for example, be uniquely specified by the quantization step size Δ. The decoder mapping of quantization indexes q to reconstructed weight parameters t′ may, for example, be, in principle, given by the simple formula

t′=q·Δ.

In this context, the term “independent scalar quantization” may, for example, refer to the property that, given the quantization index q for any weight parameter, the associated reconstructed weight parameter t′ can, for example, be determined, e.g. independently of all quantization indexes for the other weight parameters.

2.1.2 Dependent Scalar Quantization (Optional; Details are all Optional)

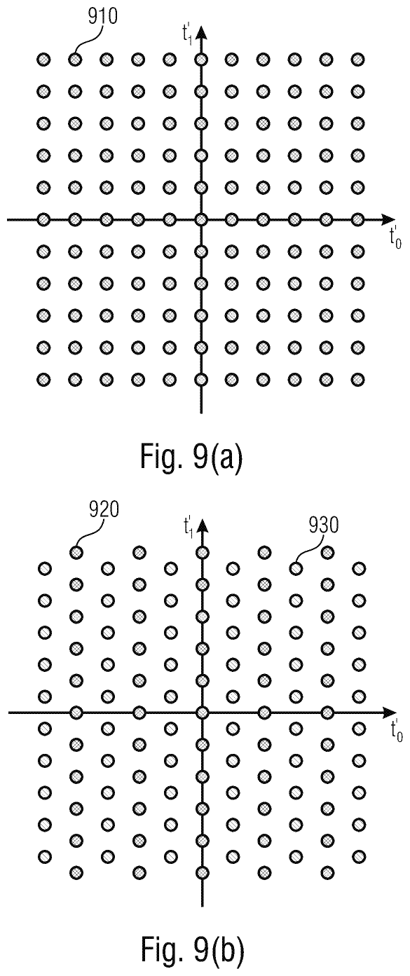

In dependent scalar quantization (DQ) the admissible reconstruction levels for a neural network parameter may, for example, depend on the selected quantization indexes for the preceding neural network parameters, for example, in reconstruction order. The concept of dependent scalar quantization may be combined with a modified entropy coding, in which the probability model selection (or, for example, alternatively, the codeword table selection) for a neural network parameter may, for example, depend on the set of admissible reconstruction levels. The advantage of the dependent quantization of neural network parameters may, for example, be that the admissible reconstruction vectors may be denser packed in the N-dimensional signal space (where N denotes the number of samples or neural network parameters in a set of samples to be processed, e.g. a layer). The reconstruction vectors for a set of neural network parameters may refer to the ordered reconstructed neural network parameters (or, for example, alternatively, the ordered reconstructed samples) of a set of neural network parameters. An example of the effect of dependent scalar quantization is illustrated in FIG. 9 for the e.g. simplest case of two neural network parameters. FIG. 9 shows an example for location of admissible reconstruction vectors for the e.g. simple case of two weight parameters: (a) Independent scalar quantization (example); (b) Dependent scalar quantization; according to embodiments of the invention. FIG. 9a shows an example of the admissible reconstruction vectors 910 (which represent points in the 2d plane) for independent scalar quantization. As it can be seen, the set of admissible values for the second neural network parameter t′₁ may not depend on the chosen value for the first reconstructed neural network parameter t′₀. FIG. 9b shows an example for dependent scalar quantization. Note that, in contrast to independent scalar quantization, the selectable reconstruction values for the second neural network parameter t′₁ may depend on the chosen reconstruction level for the first neural network parameter t′₀. In the example of FIG. 9b, there are two different sets 920, 930 of available reconstruction levels for the second neural network parameter t′₁ (illustrated by different colors or different hatchings or different types of symbols). If the quantization index for the first neural network parameter t′₀ is even ( . . . , −2, 0, 2, . . . ), any reconstruction level of the first set 920 (e.g. blue points or points having a first hatching or a first type of symbol) can, for example, be selected for the second neural network parameter t′₁. And if the quantization index for the first neural network parameter t′₀ is odd ( . . . , −3, −1, 1, 3, . . . ), any reconstruction level of the second set 930 (e.g. red points or points having a second hatching or a second type of symbol) can, for example, be selected for the second neural network parameter t′₁. In the example, the reconstruction levels for the first and second set are shifted by half the quantization step size (any reconstruction level of the second set is located between two reconstruction levels of the first set).

The dependent scalar quantization of neural network parameter may, for example, have the effect that, for a given average number of reconstruction vectors per N-dimensional unit volume, the expectation value of the distance between a given input vector of neural network parameters and the nearest available reconstruction vector may be reduced. For example, as a consequence, the average distortion between the input vector of neural network parameters and the vector reconstructed neural network parameters can, for example, be reduced for a given average number of bits. In vector quantization, this effect may be referred to as space-filling gain. Using dependent scalar quantization for sets of neural network parameters, for example, a major part of the potential space-filling gain for high-dimensional vector quantization can, for example, be exploited. And, in contrast to vector quantization, the implementation complexity of the reconstruction process (or, for example, decoding process) may, for example, be comparable to that of the related neural network parameter coding, for example, with independent scalar quantizers.

As a consequence of the above mentioned aspects, DQ may, for example, usually achieve the same distortion level at lower bitrates.

2.1.3 DQ in MPEG-7 Part 17 (Optional; Details are all Optional)

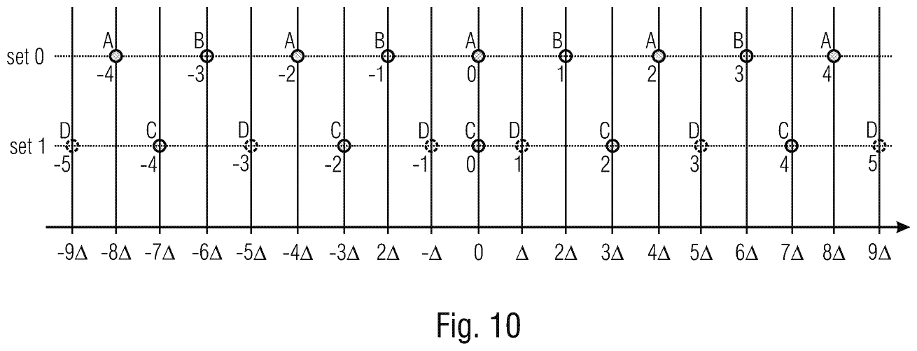

The MPEG-7 part 17 standard for compression of neural networks for multimedia content description and analysis, employs two quantizers Q1 and Q2 with different sets of reconstruction levels. Both sets may, for example, contain integer multiples of a quantization step size Δ. Q1 may, for example, contains all the even multiples of the quantization step size and 0 and Q2 may, for example, contains all the odd multiples of the quantization step size and 0. This splitting of reconstruction sets is illustrated in FIG. 10. FIG. 10 shows an example for a splitting of the sets of reconstruction levels into two subsets, according to embodiments of the invention. The two subsets of the quantization set 0 are labeled using “A” and “B”, and the two subsets of quantization set 1 are labeled using “C” and “D”.

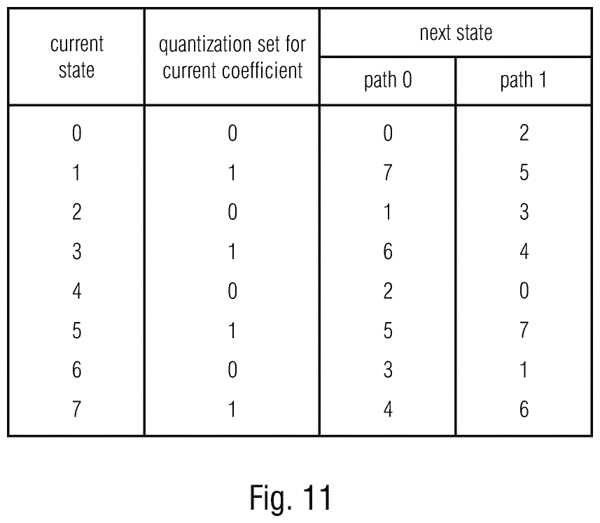

A process for switching between the sets may determine the quantizer to be applied, for example, based on chosen quantization indices for preceding neural network parameters in reconstruction order, or, for example, more precisely on the parity of the previously encoded quantization indices. This switching process may, for example, be realized by a finite state machine with 8 states (as presented in FIG. 11), where each state may, for example, be associated with one of the quantizers Q1 or Q2. FIG. 11 shows an advantageous example of a state transition table for a configuration with 8 states.

Using the concept of state transition, for example, the current state and, for example, thus, the current quantization set may be uniquely determined by the previous state (e.g. in reconstruction order) and, for example, the previous quantization index.

2.1.4 Entropy Coding (Optional; Details are all Optional)

For example, as a result of the quantization, applied in the previous step, the weight parameters may, for example, be mapped to a finite set of so-called reconstruction levels. Those can, for example, be represented by an (e.g. integer) quantizer index (e.g. also referred to as parameter level or weight level) and the quantization step size, which may, for example, be fixed for a whole layer. For example, in order to restore all quantized weight parameters of a layer, the step size and dimensions of the layer may be known by the decoder. They may, for example, be transmitted separately.

2.1.4.1 Encoding of Quantization Indexes with Context-Adaptive Binary Arithmetic Coding (CABAC)

The quantization indexes (integer representation) may, for example, then be transmitted using entropy coding techniques. For example, therefore, a layer of weights may be mapped onto a sequence of quantized weight levels, for example, using a scan. For example, a row first scan order can, for example, be used, starting with the upper-most row of the matrix, encoding the contained values from left to right. In this way, all rows may, for example, be encoded from the top to the bottom. Note that any other scan can, for example, be applied. For example, the matrix can be transposed, or flipped horizontally and/or vertically and/or rotated by 90/180/270 degree to the left or right, before applying the row-first scan

For coding of the levels CABAC (Context-Adaptive Binary Arithmetic Coding) may, for example, be used. Refer, for example, to [2] for details. So, a quantized weight level q may, for example, be decomposed in a series of binary symbols or syntax elements, which then may, for example, be handed to the binary arithmetic coder (CABAC).

In the first step, a binary syntax element sig_flag may, for example, be derived for the quantized weight level, which may, for example, specify whether the corresponding level is equal to zero. If the sig_flag is equal to one a further binary syntax element sign_flag may, for example, be derived. The bin may, for example, indicate if the current weight level is positive (e.g., bin=0) or negative (e.g., bin=1).

For example, next, a unary sequence of bins may be encoded, for example followed by a fixed length sequence, for example, as follows:

A variable k may, for example, be initialized with a non-negative integer and X may, for example, be initialized with 1«k.

One or more syntax elements abs_level_greater_X may, for example, be encoded, which may indicate, that the absolute value of the quantized weight level is greater than X. If abs_level_greater_X is equal to 1, the variable k may, for example, be updated (for example, increased by 1), then, for example, 1«k may be added to X and a further abs_level_greater_X may, for example, be encoded. This procedure may be continued until an abs_level_greater_X is equal to 0. Afterwards, a fixed length code of length k may suffice to complete the encoding of the quantizer index. For example, a variable rem=X−|q| may be or could be encoded, for example, using k bits. Or alternatively, a variable rem′ may be or could be defined as rem′=(1<<k)−rem−1 which may be encoded, for example, using k bits. Any other mapping of the variable rem to a fixed length code of k bits may alternatively be used according to embodiments of the invention.

When increasing k by 1 after each abs_level_greater_X, this approach may be identical to applying exponential Golomb coding (for example if the sign_flag is not regarded).

Additionally, if the maximum absolute value abs_max is known at the encoder and decoder side, encoding of abs_level_greater_X syntax elements may be terminated, when, for example, for the next abs_Level_greater_X to be transmitted, X>=abs_max holds.

2.1.4.2 Decoding of Quantization Indexes with Context-Adaptive Binary Arithmetic Coding (CABAC)

Decoding of the quantized weight levels (e.g. integer representation) may, for example, work analogously to the encoding. The decoder may first decode the sig_flag. If it is equal to one, a sign_flag and a unary sequence of abs_level_greater_X may follow, where the updates of k, (and, for example, thus increments of X) may or, for example, has to follow the same rule as in the encoder. For example, finally, the fixed length code of k bits may be decoded and interpreted as integer number (e.g. as rem or rem′, e.g. depending on which of both was encoded). The absolute value of the decoded quantized weight level |q| may then be reconstructed from X, and may form the fixed length part. For example, if rem was used as fixed-length part, |q|=X−rem. Or alternatively, if rem′ was encoded, |q|=X+1+rem′−(1«k). For example, as a last step, the sign may be applied or, for example, may need to be applied to |q|, for example, in dependence on the decoded sign_flag, e.g. yielding the quantized weight level q. For example, finally, the quantized weight w may be reconstructed, for example, by multiplying the quantized weight level q with the step size Δ.

In an implementation variant, k may, for example, be initialized with 0 and may be updated as follows. For example, after each abs_level_greater_X equal to 1, the, for example, required update of k may be done according to the following rule: If X>X′, k may be incremented by 1 where X′ may be a constant depending on the application. For example X′ may be a number (e.g. between 0 and 100) that may, for example, be derived by the encoder and may be signaled to the decoder.

2.1.4.3 Context Modelling

In the CABAC entropy coding, for example, most syntax elements for the quantized weight levels may be coded using a binary probability modelling. Each binary decision (bin) may be associated with a context. A context may, for example, represent a probability model for a class of coded bins. The probability for one of the two possible bin values may, for example, be estimated for each context, for example, based on the values of the bins that have been already coded with the corresponding context. Different context modelling approaches may be applied, for example, depending on the application. For example, usually, for several bins related to the quantized weight coding, the context, that may be used for coding, may be selected based on already transmitted syntax elements. Different probability estimators may be chosen, for example SBMP [4], or those of HEVC [5] or VTM-4.0 [6], for example, depending on the actual application. The choice may affect, for example, the compression efficiency and/or complexity.

A context modeling scheme that may fit a wide range of neural networks is described as follows. For decoding a quantized weight level q, for example, at a particular position (x,y) in the weight matrix (layer), a local template may be applied to the current position. This template may contain a number of other (ordered) positions like e.g. (x−1, y), (x, y−1), (x−1, y−1), etc. For example, for each position, a status identifier may be derived.

In an implementation variant (e.g. denoted Si1), a status identifier s_{x,y} for a position (x,y) may be derived as follows: If position (x,y) points outside of the matrix, or if the quantized weight level q_{x,y} at position (x,y) is not yet decoded or equals zero, the status identifier s_{x,y}=0. Otherwise, the status identifier may be or shall be s_{x,y}=q_{x,y}<0?1:2.

For a particular template, a sequence of status identifiers may be derived, and each possible constellation of the values of the status identifiers may be mapped to a context index, identifying a context to be used. The template, and the mapping may be different, for example, for different syntax elements. For example, from a template containing the (e.g. ordered) positions (x−1, y), (x, y−1), (x−1, y−1) an ordered sequence of status identifiers s_{x-1,y}, s_{x,y-1}, s_{x-1,y-1} may be derived. For example, this sequence may be mapped to a context index C=s_{x-1,y}+3*s_{x,y-}+9*s_{x-1,y-1}. For example, the context index C may be used to identify a number of contexts for the sig_flag.

In an implementation variant (denoted approach 1), the local template for the sig_flag or for the sign_flag of the quantized weight level q_{x,y} at position (x,y) may, for example, consist of only one position (x−1, y) (i.e., for example, the left neighbor). The associated status identifier s_{x-1,y} may be derived according to the implementation variant Si1.

For the sig_flag, one out of three contexts may be selected, for example, depending on the value of s_{x-,y} or for the sign_flag, one out of three other contexts may be selected, for example, depending on the value of s_{x-1,y}.

In another implementation variant (denoted approach 2), the local template for the sig flag may contain the three ordered positions (x−1, y), (x−2, y), (x−3, y). The associated sequence of status identifiers s_{x-1,y}, s_{x-2,y},s_{x-3,y} may be derived according to the implementation variant Si2.

For the sig_flag, the context index C may, for example, be derived as follows:

If s_{x-1,y}≠0, then C=0. Otherwise, if s_{x-2,y}≠0, then C=1. Otherwise, if s_{x-3,y}≠0, then C=2. Otherwise, C=3.

This may also be expressed by the following equation:

C=(s_{x-1,y}≠0)?0:((s_{x-2,y}≠0)?1:((s_{x-3,y}≠0)?2:3))

For example, in the same manner, the number of neighbors to the left may be increased or decreased, for example, so that the context index C equals the distance to the next nonzero weight to the left (e.g. not exceeding the template size).

For example, each abs_level_greater_X flag may, for example, apply an own set of two contexts. One out of the two contexts may then be chosen, for example, depending on the value of the sign_flag.

In an implementation variant, for abs_level_greater_X flags with X smaller than a predefined number X′, different contexts may be distinguished, for example, depending on X and/or on the value of the sign_flag.

In an implementation variant, for abs_level_greater_X flags with X greater or equal to a predefined number X′, different contexts may be distinguished, for example, only depending on X.

In another implementation variant, abs_level_greater_X flags with X greater or equal to a predefined number X′ may be encoded using a fixed code length of 1 (e.g. using the bypass mode of an arithmetic coder).

Furthermore, some or all of the syntax elements may also be encoded, for example, without the use of a context. Instead, they may be encoded with a fixed length of 1 bit. E.g., using a so-called bypass bin of CABAC.

In another implementation variant, the fixed-length remainder rem may be encoded, for example, using the bypass mode.

In another implementation variant, the encoder may determine a predefined number X′, may distinguish for each syntax element abs_level_greater_X with X<X′ two contexts, for example, depending on the sign, and may use, for example, for each abs_level_greater_X with X>=X′ one context.

2.1.4.4 Context Modelling for Dependent Scalar Quantization

One of the main aspects or for example, the main aspect of dependent scalar quantization may be that there may be different sets of admissible reconstruction levels (e.g. also called quantization sets) for the neural network parameters. The quantization set for a current neural network parameter may be determined, for example, based on the values of the quantization index for preceding neural network parameters. If we consider the advantageous example in FIG. 10 and compare the two quantization sets, it is obvious that the distance between the reconstruction level equal to zero and the neighboring reconstruction levels is larger in set 0 than in set 1. Hence, the probability that a quantization index is equal to 0 is larger if set 0 is used and it is smaller if set 1 is used. In an implementation variant, this effect may be exploited in the entropy coding, for example, by switching codeword tables or probability models, for example, based on the quantization sets (or states) that are used for a current quantization index.

Note that, for example, for a suitable switching of codeword tables or probability models, the path (e.g. association with a subset of the used quantization set) of all preceding quantization indexes may be or, for example, has to be known when entropy decoding a current quantization index (or, for example, a corresponding binary decision of a current quantization index). For example, therefore, it may be beneficial or even necessary that the neural network parameters are coded in reconstruction order. Hence, in an implementation variant, the coding order of neural network parameters may be equal to their reconstruction order. Beside that aspect, any coding/reconstruction order of quantization indexes may be possible, such as the one specified in section 2.1.4.1, and/or any other, for example, uniquely defined order.

For example, at least a part of bins for the absolute levels may typically be coded using adaptive probability models (also referred to as contexts). In an implementation variant, the probability models of one or more bins may be selected, for example, based on the quantization set (or, for example, more generally, the corresponding state variable) for the corresponding neural network parameter. The chosen probability model can, for example, depend on multiple parameters or properties of already transmitted quantization indexes, but one of the parameters may be the quantization set or state that may apply to the quantization index being coded.

In another implementation variant, the syntax for transmitting the quantization indexes of a layer may include a bin that specifies whether the quantization index is equal to zero or whether it is not equal to 0. The probability model that may be used for coding this bin may, for example, be selected among a set of two or more probability models. The selection of the probability model used may, for example, depend on the quantization set (i.e., for example, the set of reconstruction levels) that may apply to the corresponding quantization index. In another implementation variant, the probability model used may, for example, depend on the current state variable (the state variables may, for example, imply the used quantization set).

In a further implementation variant, the syntax for transmitting the quantization indexes of a layer may include a bin that may, for example, specify whether the quantization index is greater than zero or lower than zero. In other words, the bin may indicate the sign of the quantization index. The selection of the probability model used may depend on the quantization set (i.e. for example, the set of reconstruction levels) that may, for example, apply to the corresponding quantization index. In another implementation variant, the probability model used may depend on the current state variable (the state variables may imply the used quantization set).

In a further implementation variant, the syntax for transmitting the quantization indexes may include a bin that may specify whether the absolute value of a quantization index (e.g. neural network parameter level) is greater than X (for optional details refer to section 2.1.4.1). The probability model that may be used for coding this bin may, for example, be selected among a set of two or more probability models. The selection of the probability model used may depend on the quantization set (i.e., for example, the set of reconstruction levels) that may apply to the corresponding quantization index. In another implementation variant, the probability model used may depend on the current state variable (e.g. the state variables implies the used quantization set).

One aspect according to embodiments is that the dependent quantization of neural network parameters may be combined with an entropy coding, in which the selection of a probability model for one or more bins of the binary representation of the quantization indexes (which are also referred to as quantization levels) may, for example, depend on the quantization set (e.g. set of admissible reconstruction levels) and/or a corresponding state variable, for example, for the current quantization index. The quantization set (and/or state variable) may be given by the quantization indexes (and/or a subset of the bins representing the quantization indexes), for example, for the preceding neural network parameters in coding and reconstruction order.

In an implementation variant, the described selection of probability models may, for example, be combined with one or more of the following entropy coding aspects:
The absolute values of the quantization indexes may be transmitted, for example, using a binarization scheme that may consist of a number of bins that may be coded using adaptive probability models and, if the adaptive coded bins do not already completely specify the absolute value, a suffix part that may be coded in the bypass mode of the arithmetic coding engine (e.g. non-adaptive probability model with a pmf (0.5, 0.5), for example, for all bins). In an implementation variant, the binarization used for the suffix part may, for example, depend on the values of the already transmitted quantization indexes.
The binarization for the absolute values of the quantization indexes may include an adaptively coded bin that may, for example, specify whether the quantization index is unequal to 0. The probability model (as referred to a context) used for coding this bin may be selected among a set of candidate probability models. The selected candidate probability model may not only be determined by the quantization set (e.g. set of admissible reconstruction levels) and/or state variable for the current quantization index, but, in addition, it may, for example, also be determined by already transmitted quantization indexes for the layer. In an implementation variant, the quantization set (and/or state variable) may determine a subset (e.g. also called context set) of the available probability models and the values of already coded quantization indexes may determine the used probability model inside this subset (context set). In other words, for example, according to embodiments of the invention a subset (e.g. also called context set) of the available probability models may be determined based on the quantization set (and/or state variable) and/or the used probability model inside this subset (context set) may, for example, be determined based on the values of already coded quantization indexes.
In an implementation variant, the used probability model inside a context set may be determined, for example, based on the values of the already coded quantization indexes, for example, in a local neighborhood of the current neural network parameter. In the following, some example measures are listed that can, for example, be derived based on the values of the quantization indexes in the local neighborhood and can, for example, then, be used for selecting a probability model of the pre-determined context set:
   The signs of the quantization indexes not equal to 0, for example, inside the local neighborhood.
   The number of quantization indexes not equal to 0, for example, inside the local neighborhood. This number can, for example, possibly be clipped to a maximum value.
   The sum of the absolute values of the quantization indexes, for example, in the local neighborhood. This number can, for example, be clipped to a maximum value.
   The difference of the sum of the absolute values of the quantization indexes, for example, in the local neighborhood and number of quantization indexes not equal to 0, for example, inside the local neighborhood. This number can, for example, be clipped to a maximum value.

The binarization for the absolute values of the quantization indexes may include one or more adaptively coded bins that may, for example, specify whether the absolute value of the quantization index is greater than X. The probability models (as referred to a context), for example, used for coding these bins may be selected, for example, among a set of candidate probability models. The selected probability models may not only be determined by the quantization set (e.g. set of admissible reconstruction levels) and/or state variable for the current quantization index, but, in addition, it may also be determined by already transmitted quantization indexes for the layer. In an implementation variant, the quantization set (or state variable) may determine a subset (also called context set) of the available probability models and the data of already coded quantization indexes may determine the used probability model inside this subset (e.g. context set). For selecting the probability model, any of the methods described above (e.g. for the bin specifying whether a quantization index is unequal to 0) can be used according to embodiments of the invention.

### 3 Aspects of the Invention

Embodiments according to the invention describe and/or comprise methods for encoding of incremental updates of neural networks, where, for example, a reconstructed network layer may be a composition of an existing base layer (e.g. of a base model) and, for example, one or more incremental update layers, that may be encoded and/or transmitted separately.

3.1 Concept of Base Model and Update Models

The concept according to embodiments of the invention introduces, for example, a neural network model according to section 1 which can, for example, be considered as a full model in a sense that an output can be computed on a given input. In other words, embodiments according to the invention may comprise a neural network model according to section 1. This model is denoted as base model N_{B}. Each base model may consist of layers, which are denoted as base-layers L_{B1}, L_{B2}, . . . , L_{Bj}. A base-layer may contain base values, that may, for example, be chosen such that they can efficiently be represented and/or compressed/transmitted, for example, in a first step, e.g. a first step of a method according to embodiments of the invention. For example, additionally, the concept introduces update models (N_{U1}, N_{U2}, . . . , N_{UK}), which may have a similar or, for example, even identical architecture as the base model. In other words, embodiments according to the invention may comprise update models (N_{U1}, N_{U2}, . . . , N_{UK}). The update model may, for example, not be a full model in the sense mentioned above. Instead, it may be combined with a base model, for example, using a composition method, such that they, e.g. the base model and the update model, form a new full model N_{B1}. This model itself can, for example, serve as base model for further update models. An update model N_{Uk} may consist of layers, denoted as update layers L_{Uk,1}, L_{Uk,2}, . . . , L_{Uk,j}. An update layer may contain base values, that may, for example, be chosen such that they can efficiently be represented and/or compressed/transmitted separately.

The update model may be the outcome of an (e.g. additional) training process, for example, applied to the base model, for example, at the encoder side. Several composition methods, for example, depending on the type of updates provided by the update model may be applied according to embodiments. Note that the methods described within this invention may not be restricted to any specific type of updates/composition method, but may, for example, be applicable to any architecture using the base model/update model approach.

In an advantageous embodiment the k-th update model N_{Uk} may contain layers L_{Uk,j} with differential values (also denoted as incremental updates) that may be added to corresponding layers of a base model L_{Bj}, for example, to form a new model layer L_{Nk,j} according to:

L_{Nkj}=L_{Bj}+L_{Uk,j},for all j

The new model layers may form the (e.g. updated) new model, which may, for example, then serve as base model for a next incremental update, which may be transmitted separately.

In a further advantageous embodiment the k-th update model may contain layers L_{Uk,j} with scaling factor values that may, for example, be multiplied by the corresponding base layer L_{Bj} values to form a new model L_{Nk,j} according to:

L_{Nk,j}=L_{Bi}·L_{Uk,j},for all j

The new model layers may form the (updated) new model, which may, for example, then serve as base model for a next incremental update, which may be transmitted separately.

Note, that in some cases, an update model may also contain new layers, which may replace one or more existing layers (i.e., for example, for a layer k: L_{Nk,j}=L_{Uk,j}, for all j), for example, instead of updating a layer as described above. However, according to embodiments any combination of the beforementioned updates may be performed.

3.2 Neural Network Parameter Coding of Incremental Updates

The concept, according to embodiments of the invention, of a base model and one or more incremental updates can, for example, be exploited in the entropy coding stage, for example, in order to improve the coding efficiency. The parameters of a layer may, for example, usually be represented by a multidimensional tensor. For the encoding process, for example, a plurality or even all tensors may, for example, usually be mapped to a 2D matrix, such that entities like rows and columns. This 2D matrix may, for example then be scanned in a predefined order and the parameters may be encoded/transmitted. Note that the methods described in the following are not restricted to 2D matrices. The methods according to embodiments may be applicable to all representations of neural network parameters that provide parameter entities of known size, like e.g. rows, columns, blocks etc. and/or a combination of them. The 2D Matrix representation is used in the following for a better understanding of the methods. In general, according to embodiments, tensors comprising an information about neural network parameters may, for example, be mapped to rows and columns of multidimensional matrices.

In an advantageous embodiment the parameters of a layer may be represented as a 2D matrix, which may, for example, provide entities of values like rows and columns.

3.2.1 Row or Channel Skip Mode

For example, usually the magnitude of the values of an update model may be smaller compared to a, for example, full (base) model. For example, often a significant number of values may be zero which may also further be amplified by the quantization process. For example, as a result, the layers to be transmitted may contain long sequences of zeros, which may mean that some of the rows of the 2D matrix may be completely zero.

This can, for example, be exploited by introducing a flag (skip_row_flag), for example, for each row, which may specify whether all the parameters in a row are equal to zero or not. If the flag is equal to one (skip_row_flag==1) no further parameters may be encoded for that row. At the decoder side, if the flag is equal to one, no parameter may be decoded for this row. Instead, they, e.g. such parameters, may be assumed to be 0.

A variant according to embodiments here is to arrange all skip_row_flags into a flag array skip_row_flag[N] with N being the number of rows. Also, in a variant, N might be or may be signaled before the array.

For example, otherwise, if the flag is equal to zero, the parameters may be regularly encoded and decoded for this row.

For example, each of the skip_row_flags may be associated with a probability model or context model. A context model may be chosen out of a set of context models, for example, based on previously coded symbols (e.g. preceding encoded parameters and/or skip_row_flags.

In an advantageous embodiment a single context model may be applied to all skip_row_flags of a layer.

In another advantageous embodiment a context model may be chosen out of a set of two context models, for example, based on the value of the previously encoded skip_row_flag. That may be the first context model if the value of the preceding skip_row_flag is equal to zero, and the second context model if the value is equal to one. In other words, according to embodiments, the first context model may, for example be chosen if the value of the preceding skip_row_flag is equal to zero, and the second context model may, for example, be chosen if the value is equal to one.

In further advantageous embodiment a context model may be chosen out of a set of two context models based on the value of a co-located skip_row_flag, for example, in a corresponding layer of a previously encoded update and/or the base model. That may be the first context model if the value of the preceding skip_row_flag is equal to zero, and the second context model if the value is equal to one. In other words, according to embodiments, the first context model may, for example, be chosen if the value of the preceding skip_row_flag is equal to zero, and the second context model may, for example, be chosen if the value is equal to one.

In another advantageous embodiment the given number of context models, as for example in the previous embodiments, may be doubled forming two sets of context models. For example, then a set of context models may be chosen based on the value of a co-located skip_row_flag, for example, in a corresponding layer of a specific previously encoded update and/or the base model. That means the first set may, for example, be chosen if the value of the preceding skip_row_flag is equal to zero, and the second set if the value is equal to one.

A further advantageous embodiment may be equal to the preceding embodiment, but the first set of context models may be chosen if there does not exist a corresponding layer in a specific previously encoded update and/or the base model. For example, consequently, the second set may be chosen if there exists a corresponding layer in a specific previously encoded update and/or the base model.

Note, that the particular described mechanism for skipping rows may similarly apply to columns in the 2D matrix case, as well as in a generalized tensor case with N parameter dimensions, where a sub-block or sub-row of smaller dimension K (K<N) can, for example, be skipped, e.g. using the described mechanism of a skip_flag and/or skip_flag_array.

3.2.2 Improved Context Modeling for the Base-Model Update Model Structure

The concept of base models and one or more update models can, for example, be exploited in the entropy coding stage. The methods according to embodiments described here may be applicable to any entropy coding scheme that uses context models, as for example the one described in section 2.1.4.

For example, usually the separate update models (and, for example, the base model) may be correlated and, for example, available at the encoder and decoder side. This can, for example, be used in the context modeling stage, for example, to improve the coding efficiency, for example, by providing new context models and/or methods for context model selection.

In an advantageous embodiment a binarization (e.g. sig_flag, sign_flag, etc., for example, comprising said flags), context modeling and/or encoding scheme according section 2.1.4.1 may be applied.

In another advantageous embodiment the given number of context models (e.g. context set) for a symbol to be encoded may be duplicated forming two or more sets of context models. For example, then a set of context models may be chosen, for example, based on the value of a co-located parameter, for example, in a corresponding layer of a specific previously encoded update and/or the base model. That means a first set may be chosen if the co-located parameter is lower than a first threshold T₁, a second set if the value is greater or equal than threshold T₁, a third set if the value is greater or equal than a threshold T₂ etc. This procedure may be applied with more or less threshold values, for example with an arbitrary number of thresholds, e.g. a number of thresholds that may be chosen according to a specific application.

In an advantageous embodiment which may be equal to the previous embodiment, a single threshold T₁=0 may be used.

In another advantageous embodiment the given number of context models (e.g. context set) for a symbol to be encoded may be duplicated forming two or more sets of context models. For example, then a set of context models may be chosen, for example, based on a set of values, for example, consisting of a co-located parameter and/or neighboring values (e.g. a or several spatial neighbors of the co-located parameter), for example, in a corresponding layer of a specific previously encoded update and/or the base model.

In an advantageous embodiment, for example partially equal to or equal to the previous embodiment, a first set, e.g. a first set of context models, may be chosen, if the sum of the values (or, for example, absolute values) within the template, e.g. a template of the set of values consisting of the co-located parameter and/or the neighboring values, is lower than a first threshold T₁, a second set, e.g. a second set of context models, if the sum is greater or equal than threshold T₁, a third set, e.g. set of context models, if the sum is greater or equal than a threshold T₂ etc. This procedure may be applied with more or less threshold values, for example with an arbitrary number of thresholds, e.g. a number of thresholds that may be chosen according to a specific application.

In a particularly advantageous embodiment, for example partially equal to or equal to the previous embodiment, the template may comprise the co-located parameter and the left neighbor of the co-located parameter and a single threshold T₁=0 may be used.

In another advantageous embodiment a context model out of a set of context models for a syntax element may be chosen based on a set of values, for example, consisting of a co-located parameter and/or neighboring values (e.g. a or several spatial neighbors of the co-located parameter), for example, in a corresponding layer of a specific previously encoded update and/or the base model.

In an advantageous embodiment, for example partially equal to or equal to the previous embodiment, a first context model may be chosen, if the sum of the values (or, for example, absolute values) within the template, e.g. a template of the set of values consisting of the co-located parameter and/or the neighboring values, is lower than a first threshold T₁, a second context model if the sum is greater or equal than threshold T₁, a third context model if the value is greater or equal than a threshold T₂ etc. This procedure may be applied with more or less threshold values, for example with an arbitrary number of thresholds, e.g. a number of thresholds that may be chosen according to a specific application.

In a particularly advantageous embodiment, for example partially equal to or equal to the previous embodiment, the template may comprise the co-located parameter and the left neighbor of the co-located parameter and a single threshold T₁=0 may be used.

In further advantageous embodiment the given number of context models (e.g. context set) for a symbol to be encoded may be duplicated forming two or more sets of context models. For example, then a set of context models may be chosen based on the absolute value of a co-located parameter, for example, in a corresponding layer of a specific previously encoded update and/or the base model. That means the first set may be chosen if the absolute value of the co-located parameter is lower than a first threshold T₁, a second set if the absolute value is greater or equal another threshold T₁, a third set if the absolute value is greater or equal than a threshold T₂ etc. This procedure may be applied with more or less threshold values, for example with an arbitrary number of thresholds, e.g. a number of thresholds that may be chosen according to a specific application.

In an advantageous embodiment which may be equal to the previous embodiment a sig_flag may be encoded which may indicate if a current value to be encoded is equal to zero or not, which may employ a set of context models. The embodiment may use a single threshold T₁=1. According to embodiments a set of context models may, for example, be chosen in dependence of a sig_flag indicating whether a current value to be encoded is equal to zero or not.

Another advantageous embodiment may be equal to the previous embodiment, but instead of a sig_flag a sign_flag may be encoded which may indicate the sign of a current value to be encoded.

A further advantageous embodiment may be equal to the previous embodiment but instead of a sig_flag a abs_level_greater_X may be encoded which may indicate whether the current value to be encoded is greater than X.

In further advantageous embodiment the given number of context models (e.g. context set) for a symbol to be encoded may be doubled forming two sets of context models. For example, then a set of context models may be chosen depending on whether there is a corresponding previously encoded update (and/or base) model or not. The first set of context models may be chosen if there is not a corresponding previously encoded update (and/or base) model, and the second set, otherwise.

In another advantageous embodiment a context model out of a set of context models for a syntax element may be chosen based on the value of a co-located parameter, for example, in a specific corresponding previously encoded update (and/or base) model. That means a first model may be chosen if the co-located parameter is lower than a threshold T₁, a second model if the value is greater or equal than threshold T₁, a third set if the value is greater or equal than another threshold T₂ etc. This procedure may be applied with more or less threshold values, for example with an arbitrary number of thresholds, e.g. a number of thresholds that may be chosen according to a specific application.

In advantageous embodiment, for example, equal to the previous embodiment a sign_flag may be encoded which may indicate the sign of a current value to be encoded. A first threshold for the context model selection process may be T₁=0 and a second threshold may be T₂=1.

In another advantageous embodiment a context model out of a set of context models for a syntax element may be chosen based on the absolute value of a co-located parameter in a specific corresponding previously encoded update (and/or base) model. That means a first model may be chosen if the absolute value of the co-located parameter is lower than a threshold T₁, a second model if the value is greater or equal than threshold T₁, a third model if the value is greater or equal than threshold T₂ etc. This procedure may be applied with more or less threshold values, for example with an arbitrary number of thresholds, e.g. a number of thresholds that may be chosen according to a specific application.

In an advantageous embodiment, for example, equal to the previous embodiment a sig_flag may be encoded which may indicate whether a current value to be encoded is equal to zero or not. It, for example an apparatus according to this embodiment, may employ a first threshold set to T₁=1 and second threshold set to T₂=2.

In another advantageous embodiment, for example, equal to the previous embodiment instead of a sig_flag a abs_level_greater_X flag may be encoded which may indicate whether a current value to be encoded is greater than X. Additionally only one threshold may be employed which may be set to T₁=X.

Note that any of the above mentioned embodiments and aspects and features thereof can be combined with one or more of the other embodiments and aspects and features thereof.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus.

The inventive encoded representation of neural network parameters can be stored on a digital storage medium or can be transmitted on a transmission medium such as a wireless transmission medium or a wired transmission medium such as the Internet.

Depending on certain implementation requirements, embodiments of the invention can be implemented in hardware or in software. The implementation can be performed using a digital storage medium, for example a floppy disk, a DVD, a CD, a ROM, a PROM, an EPROM, an EEPROM or a FLASH memory, having electronically readable control signals stored thereon, which cooperate (or are capable of cooperating) with a programmable computer system such that the respective method is performed.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are performed by any hardware apparatus.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

### REFERENCES

[1] S. Chetlur et al., “cuDNN: Efficient Primitives for Deep Learning,” arXiv: 1410.0759, 2014
[2] MPEG, “Text of ISO/IEC DIS 15938-17 Compression of Neural Networks for Multimedia Content Description and Analysis”, Document of ISO/IEC JTC1/SC29/WG11, w19764, OnLine, Oct. 2020
[3] D. Marpe, H. Schwarz und T. Wiegand, “Context-Based Adaptive Binary Arithmetic Coding in the H.264/AVC Video Compression Standard,” IEEE transactions on circuits and systems for video technology, Vol. 13, No. 7, pp. 620-636, July 2003.
[4] H. Kirchhoffer, J. Stegemann, D. Marpe, H. Schwarz und T. Wiegand, “JVET-K0430-v3-CE5-related: State-based probalility estimator,” in JVET, Ljubljana, 2018.
[5] ITU—International Telecommunication Union, “ITU-T H.265 High efficiency video coding,” Series H: Audiovisual and multimedia systems—Infrastructure of audiovisual services—Coding of moving video, April 2015.
[6] B. Bross, J. Chen und S. Liu, “JVET-M1001-v6—Versatile Video Coding (Draft 4),” in JVET, Marrakech, 2019.
[7] S. Wiedemann et al., “DeepCABAC: A Universal Compression Algorithm for Deep Neural Networks,” in IEEE Journal of Selected Topics in Signal Processing, vol. 14, no. 4, pp. 700-714, May 2020, doi: 10.1109/JSTSP.2020.2969554.

1. Apparatus for decoding neural network parameters, which define a neural network,
wherein the apparatus is configured to decode an update model which defines a modification of one or more layers of the neural network, and
wherein the apparatus is configured modify parameters of a base model of the neural network using the update model, in order to acquire an updated model, and
wherein the apparatus is configured to evaluate a skip information indicating whether a sequence of parameters of the update model is zero or not.

2. Apparatus according to claim 1,
wherein the update model describes differential values, and
wherein the apparatus is configured to additively or subtractively combine the differential values with values of parameters of the base model, in order to acquire values of parameters of the updated model.

3. Apparatus according to claim 1,
wherein the apparatus is configured to combine differential values or differential tensors L_{Uk,j}, which are associated with a j-th layer of the neural network, with base value parameters or base value tensors L_{Bj}, which represent values of parameters of a j-th layer of a base model of the neural net, according to
L_{Nkj}=L_{Bi}+L_{Uk,j},for all j, or for all j for which the update model comprises a layer
In order to acquire updated model value parameters or updated model value tensors L_{Nkj}, which represent values of parameters of a j-th layer of an updated model having model index k of the neural network.

4. Apparatus according to claim 1,
wherein the neural network parameters comprise weight values defining weights of neuron interconnections which emerge from a neuron or which lead towards a neuron.

5. Apparatus according to claim 1,
wherein a sequence of neural network parameters comprises weight values which are associated with a row or column of a matrix.

6. Apparatus according to claim 1,
wherein the skip information comprises a flag indicating whether all parameters of a sequence of parameters of the update model are zero or not

7. Apparatus according to claim 1,
wherein the apparatus is configured to selectively skip a decoding of a sequence of parameters of the update model in dependence on the skip information.

8. Apparatus according to claim 1,
wherein the apparatus is configured to selectively set values of a sequence of parameters of the update model to a predetermined value in dependence on the skip information.

9. Apparatus according to claim 1,
wherein the skip information comprises an array of skip flags indicating whether all parameters of respective sequences of parameters of the update model are zero or not.

10. Apparatus according to claim 1,
wherein the apparatus is configured to selectively skip a decoding of respective sequences of parameters of the update model in dependence on respective skip flags associated with respective sequences of parameters.

11. Apparatus according to claim 1,
wherein the apparatus is configured to evaluate an array size information describing a number of entries of the array of skip flags.

12. Apparatus according to claim 1,
wherein the apparatus is configured to apply a single context model for a decoding of all skip flags associated with a layer of the neural network.

13. Apparatus according to claim 1,
wherein the apparatus is configured to select a context model out of the selected set of context models in dependence on one or more previously decoded symbols of a currently decoded update model.

14. Apparatus for encoding neural network parameters, which define a neural network,
wherein the apparatus is configured to encode an update model which defines a modification of one or more layers of the neural network, and
wherein the apparatus is configured to provide the update model, such that the update model enables a decoder to modify parameters of a base model of the neural network using the update model, in order to acquire an updated model, and
wherein the apparatus is configured to provide and/or determine a skip information indicating whether a sequence of parameters of the update model is zero or not.

15. Method for decoding neural network parameters, which define a neural network, the method comprising
decoding an update model which defines a modification of one or more layers of the neural network, and
modifying parameters of a base model of the neural network using the update model, in order to acquire an updated model, and
evaluating a skip information indicating whether a sequence of parameters of the update model is zero or not.

16. Method for encoding neural network parameters, which define a neural network, the method comprising
encoding an update model which defines a modification of one or more layers of the neural network, and
providing the update model, in order to modify parameters of a base model of the neural network using the update model, in order to acquire an updated model, and
providing and/or determining a skip information indicating whether a sequence of parameters of the update model is zero or not.

17. Non-transitory digital storage medium having a computer program stored thereon to perform the method for decoding neural network parameters, which define a neural network, the method comprising
decoding an update model which defines a modification of one or more layers of the neural network, and
modifying parameters of a base model of the neural network using the update model, in order to acquire an updated model, and
evaluating a skip information indicating whether a sequence of parameters of the update model is zero or not,
when said computer program is run by a computer.

18. Non-transitory digital storage medium having a computer program stored thereon to perform the method for encoding neural network parameters, which define a neural network, the method comprising
encoding an update model which defines a modification of one or more layers of the neural network, and
providing the update model, in order to modify parameters of a base model of the neural network using the update model, in order to acquire an updated model, and
providing and/or determining a skip information indicating whether a sequence of parameters of the update model is zero or not,
when said computer program is run by a computer.

19. Encoded representation of neural network parameters, comprising:
an update model which defines a modification of one or more layers of the neural network, and
a skip information indicating whether a sequence of parameters of the update model is zero or not.
